(19) United States
(12) Patent Application Publication
(10) Pub. No.: US 2026/0253853 A1
(43) Pub. Date: Aug. 27, 2026

(54) DYNAMIC UNIFORMITY CONTROL FOR MAGNETRON SPUTTERING PROCESSES

(71) Applicant: SOLERAS ADVANCED COATINGS BV, Deinze (BE)

(72) Inventors: Wilmert DE BOSSCHER, Drongen (BE); Ivan VAN DE PUTTE, Waregem (BE)

(21) Appl. No.: 19/163,059

(22) PCT Filed: Feb. 9, 2024
(86) PCT No.: PCT/EP2024/053383

§ 371 Date: Sep. 8, 2025

(30) Foreign Application Priority Data
Mar. 13, 2023 (BE) BE2023/5181

(51) Int. Cl. H01J 37/34; C23C 14/34; C23C 14/35

(52) U.S. Cl. CPC H01J 37/3405; C23C 14/3407; C23C 14/35; H01J 37/3417; H01J 37/342; H01J 37/3423; H01J 37/3452; H01J 37/3455

(57) ABSTRACT

A magnetron assembly for a sputter apparatus, a method of manufacture and the use of the same for coating applications of non-flat substrates is disclosed. The magnetron assembly includes a first and a second support member for mounting thereon an elongated sputter target and a magnet assembly, respectively, and further includes independent first and second drive means configured to impart rotary motion to the first and second support member, respectively. Axes of rotation of the first and second support member are parallel and preferably substantially coaxial. The magnet assembly includes a longitudinally extending magnetic structure that defines a closed-loop confinement region for a plasma generated under sputtering conditions of the magnetron sputter apparatus. At least a central portion of the magnetic structure, terminated by respective end portions of the magnetic structure, has a varying azimuthal position between the respective end portions of the magnetic structure.

### FIELD OF THE INVENTION

The present invention relates to the field of magnetron sputtering processes, magnetron sputter equipment and coatings obtained thereby. More specifically, the invention relates to dynamic uniformity control of material films to be deposited by magnetron sputtering on surfaces that have a curved geometry or require a position-dependent film thickness.

### BACKGROUND OF THE INVENTION

Magnetron sputtering is a material layer deposition technique that uses the plasma confinement effect of magnetic field tunnels to achieve high plasma densities and related sputter deposition rates. Sputter coating equipment has been successfully adapted to meet industrial needs of coating large-area substrates in little time, and yet achieving good control over film properties such as thickness uniformity. Therefore, number of industries, ranging from flat panel display technology (TFT based on LCD or OLED technology) to low-emissivity and anti-reflection glass coating, rely on magnetron sputter techniques during product manufacture. Continuous sputter coating with inline deposition systems, in which the substrate moves relative to the sputter target, are offering the benefits of high throughput and flexibility. Complex coating stacks, e.g. multi-layered coatings having a varying number of coating layers and/or different coating layer compositions, can be reliably sputtered onto moving substrates that are transported across multiple sputter targets arranged in a same deposition chamber or different deposition chambers along the coating line.

DC, AC or RF sputtering using planar or cylindrical magnetron configurations is known in the art. It is common to these configurations to provide a magnet assembly or magnetron that is adapted to generate a plasma confinement region, referred to as racetrack, plasma channel or plasma/magnetic tunnel, adjacent to the sputter surface of a planar or cylindrical target. Target erosion then follows the shape of the racetrack while the eroded material is deposited onto a substrate. In cylindrical magnetrons, the targets are hollow and the target material is tubular, i.e. provided as a tube or applied onto a carrier tube. Magnets are assembled into a static magnetic structure that is mounted in the interior of the rotatable hollow target. Rotating the hollow target about its cylindrical axis and around the static magnetic structure mounted therein, continuously sweeps the sputter target surface under the plasma channel during the sputter process, thereby avoiding the formation of erosion grooves in the target material and increasing target utilization.

The quality of the sputtered products often depends on and is assessed in terms of thickness uniformity of the deposited layer on the substrate. Even little variations thereof can give rise to a sub-optimal performance and variable quality of the final product. Consequently, a tight control of the thickness uniformity across the whole substrate surface area is necessary. Deviations in the targeted thickness uniformity of the coated layer may be caused by non-uniformities in the partial pressure of one or more sputtering gases (e.g. argon or reactive gas), the magnetic field distribution, the electric field distributions, sputter target surface (e.g. target surface morphology and/or composition), and geometric positioning of shields, anodes or substrate relative to the sputter target.

Various techniques for reducing or preventing variations in the desired layer thickness uniformity have already been suggested in the prior art, including:
applying minute movements to magnetic segments of the magnet assembly, magnetic shunts, and/or the substrate to compensate for local variations in the thickness of the deposited layer,
locally deforming a magnet bar of the magnet assembly inside the cylindrical target,
optimizing the mechanical position/orientation of the sputter source, such as adjusting the distance between the sputter target and the substrate and/or adjusting the electrical power supplied to the sputter target.
use of shimming plates for realizing a variable shield opening along the target length.

EP 0820088 A3 discloses a planar scanning magnetron assembly for thin film sputtering onto curved substrates. The magnetron comprises a flat cam follower plate with a plurality of guide slots that cooperate with a corresponding plurality of contour following actuators. A vertical positioning rod connects each contour following actuator to a magnet segment of the magnetron assembly. A tracking frame ties all contour following actuators together so that they move in unison while the magnetron assembly sweeps across the target assembly. A control system receives elevation control data and sets the vertical position of each magnet segment at each swept location of the magnetron through the individual contour followers. The elevation control data causes the magnet segments to moves in a programmed manner according to a programmed surface profile. A contour following system for a magnetron assembly of the type described lacks the necessary compactness for an installation inside hollow cylindrical targets. It also leads to non-uniform erosion profiles across the target assembly, which are dependent on each magnet segment. The scanning magnetron assembly is not suitable for sputter coating of wide substrates at high throughput.

WO 2016/005476 A1 discloses a magnetron sputter apparatus which provides drive means for moving a cylindrical sputter target along a trajectory in space. The sputter target is rotatably mounted on an end block. The trajectory may be defined with respect to curved substrates moving past the sputter target in such a way that the target-to-substrate surface distance remains constant. This ensures that layers of uniform thickness are deposited onto the substrate which have a single principal curvature direction aligned with a substrate transport direction. A magnetron sputter apparatus with a movable end block of the type described results in a non-stationary sputter source, which is more difficult to assemble and maintain. The end block itself has to be situated in the vacuum chamber, which limits the access to the end block for inspection and repair without venting. Moreover, adequate sealing of the end blocks, the connected drive means, the power and coolant supply lines is significantly more challenging if the end blocks are placed into vacuum.

Document U.S. Pat. No. 6,375,814 B1, 23 Apr. 2002 discloses a stationary sputtering magnetron with a rotating cylindrical target and a stationary magnet assembly. The magnet assembly is adapted to produce an elongate plasma race-track on the surface of the target. The race-track has parallel tracks over a substantial portion of its length and is closed at each end by end portions. A spacing between the tracks of the race-track is increased locally to materially affect sputtering onto a substrate. As a result thereof, shields may no longer be needed to control the film thickness uniformity over substrates and a non-uniform consumption of the target material at the end portions of the target can be overcome.

There is still a need for stationary cylindrical magnetron sputter sources that are easy to control and capable of uniformly coating substrates with arbitrary surface curvature directions.

### SUMMARY OF THE INVENTION

It is an object of embodiments of the present invention to provide devices and methods provide good coating uniformity across the length and width dimension of substrates having curved or inclined surfaces to be coated by magnetron sputtering.

The above objective is accomplished by an assembly, apparatus and method according to the present invention.

In a first aspect, the present invention relates to a magnetron assembly for a magnetron sputter apparatus. The magnetron assembly comprises a first support member for mounting of an elongated sputter target, a second support member for mounting of a magnet assembly, a first drive means configured to impart rotary motion to the first support member, and an independent second drive means configured to impart rotary motion to the second support member, separately from the rotary motion imparted to the first support member. The axes of rotation of the first support member and the second support member are parallel and preferably substantially coaxial. The magnetron assembly also comprises the magnet assembly which has an elongated magnetic structure that extends longitudinally in the direction of the rotation axis of the second support member. The magnetic structure defining a closed-loop confinement region for a plasma generated under sputtering conditions of the magnetron sputter apparatus. A central portion of the magnetic structure is terminated by respective end portions and has an azimuthal position relative to the rotation axis of the second support member. The azimuthal position of the central portion varies between the respective end portions of the magnetic structure.

The magnetic structure may comprise elongated magnetic tracks that project radially outwards from a magnetic base member. One or more of the magnetic tracks may be bent in the azimuthal direction in the central portion of the magnetic structure. The magnetic base member may be a support tube made from a magnetic material, which acts as a pole piece with respect to permanent magnets the magnetic tracks are composed of.

According to some embodiments of the invention, the first support member and first drive means are comprised by, e.g. form part of, a first end block and the second support member and the second drive means are comprised by, e.g. form part of, a second end block. In such embodiments, the two end blocks are facing each other and are typically separated by a distance in the longitudinal direction, which corresponds to the length of the hollow target, and the magnet assembly and the hollow target surrounding the magnet assembly are mounted on the respective end block and extend between the two end blocks.

According to other embodiments of the invention, the first and second support member and the first and second drive means are all comprised by, e.g. form part of, one and the same end block. The magnet assembly and the hollow target surrounding the magnet assembly are mounted at one end onto the end block. The other end of the magnet assembly and the hollow target may be a free end that is terminated and protected by an end flange, or is also mounted onto a different end block.

The first and second drive means may each comprise or consist of a drive assembly. The drive assembly may comprise a drive engine or driving force generator, e.g. an electrical motor, and a force transmission structure, e.g. including one or more of torque converter, gear system, transmission chain or belt.

In a second aspect, the present invention relates to a method of manufacturing a magnetron assembly for use in magnetron sputter apparatus that is suitable for sputter-coating of non-planar substrates in a continuous coating process, or sputter-coating substrates with a time-variant material flux across the substrate. The method comprises the steps of:
obtaining shape information with regard to the curved substrates to be coated,
providing a magnetic structure as part of a magnet assembly and rotatably mounting the magnet assembly on an end block of the magnetron assembly, wherein the magnetic structure extends longitudinally along a rotation axis of the magnet assembly and defines a closed-loop confinement region for a plasma generated under sputtering conditions of the magnetron sputter apparatus,
determining a shape for a central portion of the magnetic structure, terminated by respective end portions of the magnetic structure, based on the shape information obtained with regard to the curved substrates, and
varying an azimuthal position of the magnetic structure in a central portion of the magnetic structure, arranged between respective end portions of the magnetic structure, in accordance with therefor determined shape.

In a further aspect, the present invention relates to a method of sputter-coating curved, non-flat or inclined substrate surfaces. The method comprises the steps of:
transporting a curved substrate to be coated past a magnetron assembly obtained by carrying out the steps of methods according to the second aspect,
synchronizing a rotational movement of the magnet assembly about its rotation axis with said transporting of the curved substrate past the magnetron assembly, the magnet assembly being mounted inside a hollow sputter target rotatably mounted onto the end block of the magnetron assembly such that the axes of rotation of the sputter target and the magnet assembly are substantially parallel.

According to some embodiments of the invention, the sputter-coating method further comprises the step of orienting and maintaining an orientation of the curved substrate relative to the magnetron assembly during transport such that an axis of curvature of the curved substrate is parallel to the rotation axis of the magnet assembly.

In embodiments of the invention, the rotational movement of the magnet assembly about its rotation axis may be performed in accordance with a pre-calculated control trajectory for the rotation angle of the magnet assembly, e.g. assigning a particular rotation angle to each one of a plurality of (control) time points. The sense of rotation of the magnet assembly about its rotation axis may be unidirectional (e.g. either clockwise or anti-clockwise) during sputter-coating of the substrate surface, or may be bi-directional (e.g. either both clockwise and anti-clockwise rotation movements of the magnet assembly are permitted). The speed of rotation of the movement of the magnet assembly about its rotation axis may be constant or vary as a function of time and/or substrate position relative to the magnet assembly.

In yet another aspect, the present invention relates to a magnetron sputter apparatus or inline coater apparatus that includes the magnetron assembly of the first aspect of the invention.

According to some embodiments of the invention, the magnetron sputter apparatus or inline coater apparatus that includes the magnetron assembly of the first aspect of the invention and a substrate transport system for conveying one or more substrates past the magnet assembly. The distant plane parallel to the rotation axis of the second support member of the magnetron assembly corresponds to a plane of the substrate transport system in which the substrates are conveyed past the magnet assembly. The magnetron sputter apparatus or inline coater apparatus may further comprise the elongated sputter target that is mounted on the first support member of the magnetron assembly and a shield assembly that has a shield with an opening adapted to expose a portion of the surface of the sputter target. The shield opening extends longitudinally in the direction of the rotation axis of the second support member and is coplanar with the reference line.

According to same or different embodiments, the magnetron sputter apparatus or inline coater apparatus that includes the magnetron assembly of the first aspect of the invention and a controller. The controller is configured to control a time-dependent rotation angle of the magnet assembly about the rotation axis of the second support member of the magnetron assembly and synchronize a rotational movement of the magnet assembly with a transport trajectory of a substrate past the magnet assembly.

It is an advantage of embodiments of the invention that uniform coating of curved substrates can be obtained in inline coaters. A controlled rotation of a magnetic structure with a varying angular position in its central portion is easier, faster and more reliable than a complex rotation and tuning scheme of individual nodes along a tunable magnet bar.

It is an advantage of embodiments of the invention that uniform coating of curved substrates can be obtained by control methods in which only synchronization of the substrate transport and the rotation angles of the magnet assembly is needed. This makes the control method less error-prone and more stable with regard to unexpected deviations of process parameters during the sputter coating process.

Particular and preferred aspects of the invention are set out in the accompanying independent and dependent claims. Features from the dependent claims may be combined with features of the independent claims and with features of other dependent claims as appropriate and not merely as explicitly set out in the claims.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

The above and other aspects of the invention will be apparent from and elucidated with reference to the embodiment(s) described hereinafter.

### BRIEF DESCRIPTION OF THE DRAWINGS

The invention will now be described further, by way of example, with reference to the accompanying drawings, in which:

FIG. 1 illustrates simulation results for the thickness distribution of a layer deposited onto a flat substrate surface by a conventional cylindrical magnetron sputter apparatus.

FIG. 2 and FIG. 3 illustrate simulation results for the thickness distribution of a layer deposited onto a curved substrate surface by a conventional cylindrical magnetron sputter apparatus, wherein the substrates surface is curved along a single direction.

FIG. 4 illustrates simulation results for the thickness distribution of a layer deposited onto the curved substrate surface of FIG. 3, obtained by synchronized modulation of substrate transport speed and/or the sputter target power supplied to the cylindrical magnetron sputter apparatus.

FIG. 5 and FIG. 6 illustrate simulation results for the thickness distribution of a layer deposited onto a differently oriented, curved substrate surface by a conventional cylindrical magnetron sputter apparatus, wherein the substrates surface is curved along a single direction.

FIG. 7 illustrates simulation results for the thickness distribution of a layer deposited onto the curved substrate surface of FIG. 6, obtained by magnet bar tuning of the magnet assembly inside the cylindrical magnetron sputter apparatus.

FIG. 8 to FIG. 11 illustrate simulation results for the thickness distribution of a layer deposited onto various curved substrate surfaces by a conventional cylindrical magnetron sputter apparatus, wherein the substrates surfaces have principal curvatures along a two different directions.

FIG. 12 illustrates simulation results for the thickness distribution of a layer deposited onto the curved substrate surface of FIG. 11, obtained by a combination of simultaneous tuning systems of the cylindrical magnetron sputter apparatus and substrate transport system.

FIG. 13 is a perspective view of a magnet assembly that can be used in embodiments of the invention.

FIG. 14 (A)-(F) illustrates various shapes of magnetic racetracks or plasma racetracks induced by magnetic structures in accordance with embodiments of the invention.

FIG. 15 and FIG. 16 show respective calculated dependences of the deposition profile and the normalized deposition rate on the rotation angle of a conventional magnetic bar with straight racetrack geometry.

FIG. 17A to FIG. 17C are different views of magnetron assemblies according to embodiments of the invention.

FIG. 18 explains the process uniformly coating a curved substrate with a sputter apparatus that contains a magnetron assembly, in accordance with embodiments of the invention.

FIG. 19 and FIG. 20 show alternative magnetron sputter apparatuses according to an embodiments of the invention.

FIG. 21 shows a dual magnetron sputter apparatus according to another embodiment of the invention.

FIG. 22 is a flow diagram explaining steps of a manufacturing method for the magnetron assembly, in accordance with embodiments of the invention.

FIG. 23 shows a magnetron sputter apparatus in accordance with embodiments of the invention.

The drawings are only schematic and are non-limiting. In the drawings, the size of some of the elements may be exaggerated and not drawn on scale for illustrative purposes. The dimensions and the relative dimensions do not necessarily correspond to actual reductions to practice of the invention.

Any reference signs in the claims shall not be construed as limiting the scope.

In the different drawings, the same reference signs refer to the same or analogous elements.

### DETAILED DESCRIPTION OF ILLUSTRATIVE EMBODIMENTS

The present invention will be described with respect to particular embodiments and with reference to certain drawings but the invention is not limited thereto but only by the claims.

The terms first, second and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present invention, the only relevant components of the device are A and B.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment. Furthermore, the particular features, structures or characteristics may be combined in any suitable manner, as would be apparent to one of ordinary skill in the art from this disclosure, in one or more embodiments.

Similarly it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art.

In the description provided herein, numerous specific details are set forth. However, it is understood that embodiments of the invention may be practiced without these specific details. In other instances, well-known methods, structures and techniques have not been shown in detail in order not to obscure an understanding of this description.

Designs for wind shields, sunroofs, large display panels and dashboards in the automotive sector are often using complex shapes, characterized by a non-flat, curved surface geometry. Ultrawide computer screens with a curved display area are also commercialized. As for conventional flat substrates, these curved or non-flat substrate surfaces, too, are usually equipped with anti-reflection coatings, protective coatings, or the like. Not only the large-sized area of substrates or workpieces over which a coating layer has to be deposited uniformly is impressive for these applications, e.g. 0.3*0.4 m² , 1.1*1.3 m² , 1.5*1.8 m², 1.0*6.0 m² , 2.0*2.0 m², 2.0*3.0 m² or 2.9*3.2 m² , but also the stringent tolerances on the layer thickness uniformity are. It is not unusual that product manufactures ask for magnetron sputter equipment that is capable of controlling the deposited layer thickness on the substrate accurately within +/−5% or less, e.g. to be accurate within +/−3% or +/−1%. The curved geometry and complex substrates shapes for which uniform coating is required, makes the tight control of coating layer thickness uniformity in magnetron sputter equipment even more challenging. In the following, the effect of curvature and direction of curvature on the thickness uniformity of a layer to be sputter-deposited onto the substrate surfaces is briefly discussed, as well as possible remedies and their limitations. Historically, sputter coatings for these applications have been deposited on flat substrates prior to a bending process. More recently, substrates to be coated may be bent and treated beforehand, and coating are executed subsequently on the curved substrates.

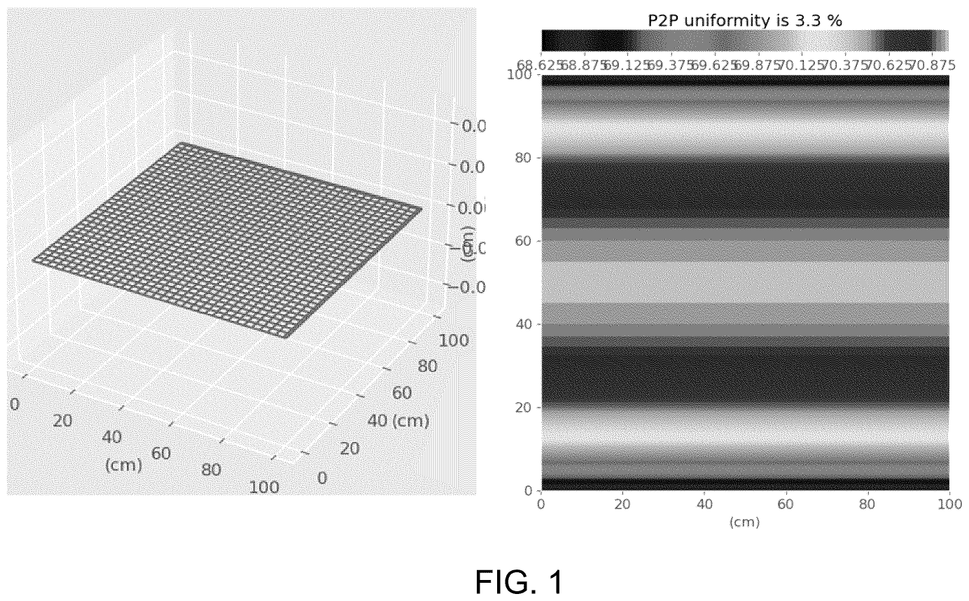

FIG. 1 shows a flat, 1.0 m² -sized square substrate and a simulated deposition layer thickness for an inline coater based on magnetron sputtering (target length: 1.5 m, target-substrate spacing: 120 mm). The simulation takes actual process parameters (e.g. power supplied to sputter target, composition and partial pressure of gases, target and substrate material, substrate transport speed, angular material ejection flux from the physical target dimensions, etc.) and inline coater geometry and configuration parameters into account and provides accurate predictions of the expected deposition layer properties. The predicted deposited layer thickness is uniform along the substrate transport direction relative to the static sputter source (first direction: horizontal axis in the figure), but varies along the length axis of the rotary sputter target, perpendicular to the substrate transport direction (second direction: vertical axis in the figure). The expected peak-to-peak thickness non-uniformity is about 3.3%. While the movement of the substrate past the sputter target has an averaging effect on the deposited layer thickness with respect to the first direction, no averaging occurs along the second direction. The steadier and more robust the substrate transport system, the better the achievable thickness uniformity along the first direction. With regard to the second direction, different parameters of the sputter apparatus determine the expected extent and profile of thickness deviation. Among these parameters appear the finite length of the sputter target relative to the substrate length (i.e. the target-substrate overlap), the surface-normal distance between the substrate upper surface (facing the sputter target) and the sputter target surface, the shield opening configuration (e.g. shield shape and width), the gas distribution in the deposition chamber, the magnetic field strength along the racetrack including possible global and local tuning of the whole or parts of the magnet assembly, the typed of electrical power delivery (e.g. AC, DC, RF power), and the geometry and position of cathodes and anodes in the sputter system.

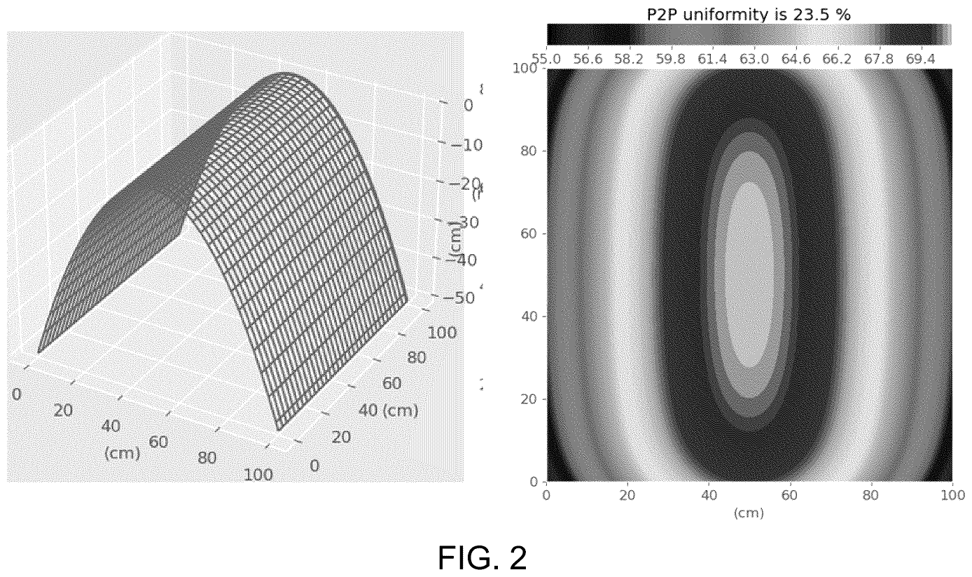

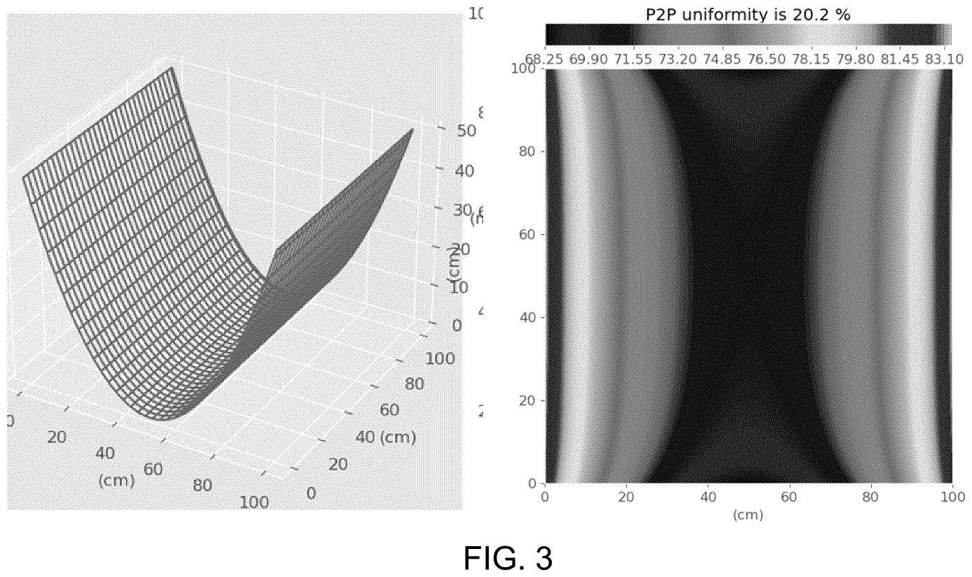

FIG. 2 and FIG. 3 show 1.0 m×1.0 m sized substrates having a curved surface geometry (height values are in mm) and corresponding simulations of the deposition layer thickness with respect to the same inline coater as simulated for the flat substrate in FIG. 1. The depicted substrate surfaces have at least one curvature component in the direction of substrate movement past the sputter source (first direction), i.e. are non-flat along lines that are tangential to the substrate surface in at least one point of the substrate surface and oriented parallelly to the substrate transport axis and perpendicularly to the length axis (central axis, rotation axis) of the rotary sputter target. In FIG. 2 and FIG. 3, the substrates are oriented such that their (only) principal direction (eigenvector of the shape operator for a given point on the substrate surface, locally defining the direction of the principal curvature in this point) is aligned with the substrate transport direction, but the corresponding principal curvature values are of opposite sign (+/−0.4 m⁻¹). In these two cases, the average thickness non-uniformity along the direction of substrate movement largely predominates in the overall thickness non-uniformity distribution, whereas the average thickness non-uniformity along the target direction (second direction) is comparable to the thickness non-uniformity of flat substrates. More specifically, the simulated average thickness of the sputter-deposited layer in FIG. 2 varies between −13.0/+8.0% along the first direction, compared to −3.0/+1.0% along the second direction. For the example substrate in FIG. 3, the simulated average thickness of the sputter-deposited layer varies between −5.0/+12.0% along the first direction and −2.0/+0.5% along the second direction. The respective values of the peak-two-peak thickness non-uniformity are 23.5% and 20.2%.

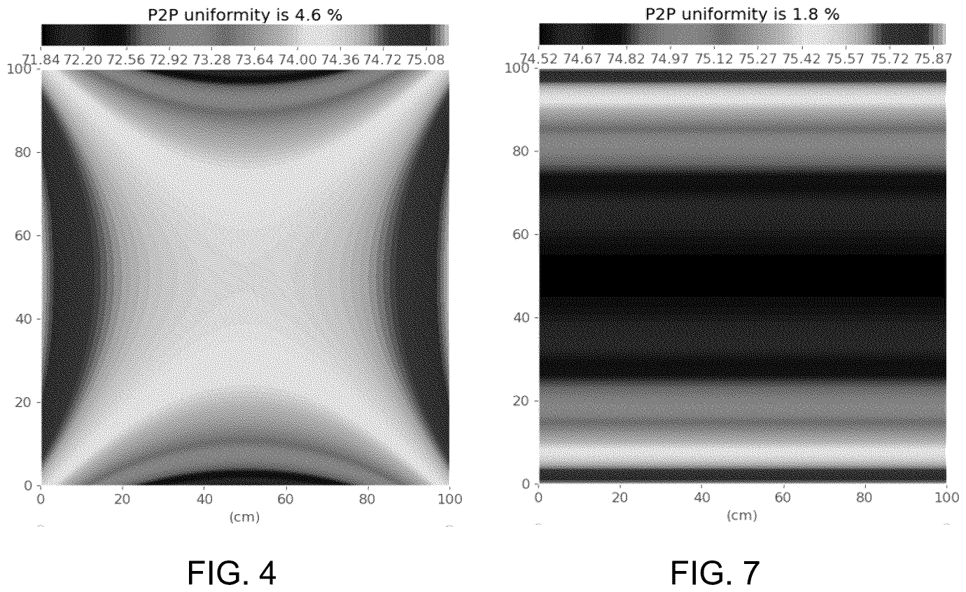

FIG. 4 presents simulation results for deposited layer thickness of the same substrate as shown in FIG. 3, but applying a synchronized target power and/or substrate transport speed modulation technique to the inline coater. As the substrate is moving below and past the sputter source, the distance between the sputter source and the curved surface of the moving substrate changes as a function of time. Here, the distance is measured in a third direction (elevation or height) that is perpendicular to both the first and the second direction. The sputtered particle flux at the substrate surface and the therewith associated deposition rate decrease as the target-to-substrate distance increases. To compensate for the varying target-to-substrate distance of the moving substrate, the electrical power supply to the sputter target and/or the substrate transport speed are preferably modulated in combination and in a synchronized matter such that the electrical power is increased and the transport speed decreased when target-to-substrate distance is growing and, in the opposite case of a shrinking target-to-substrate distance, the electrical power is decreased and/or the transport speed increased. No substantial compensation of the sputtered particle flux leaving the bombarded target surface is needed along the target length direction at any particular moment in time. This synchronized control strategy for the stationary sputter source and substrate conveyance means can reduce the large variations in the deposited layer thickness observed in FIG. 3. The simulated peak-to-peak thickness non-uniformity in FIG. 4 is now limited to 4.6%, but it takes additional efforts to implement, calibrate and monitor the synchronized control strategy.

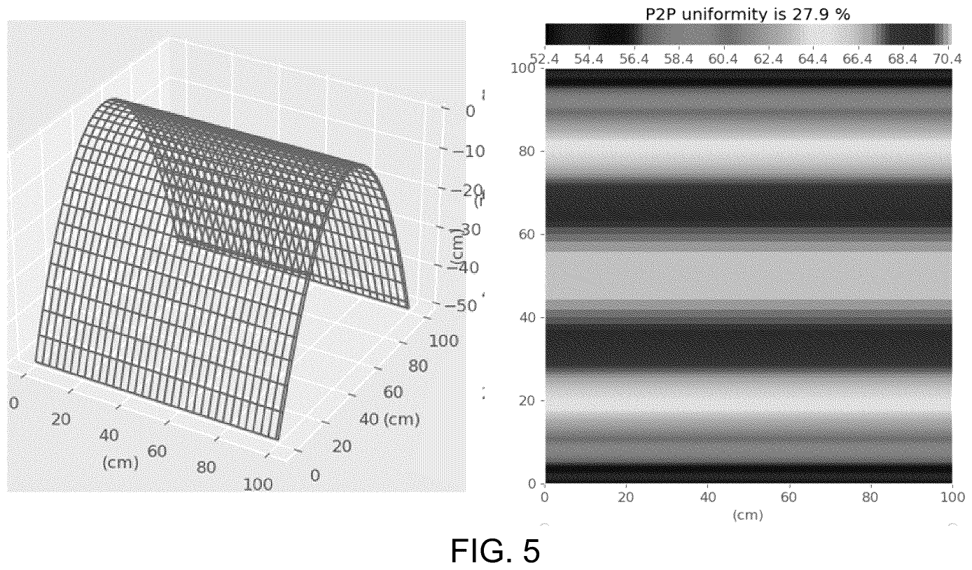

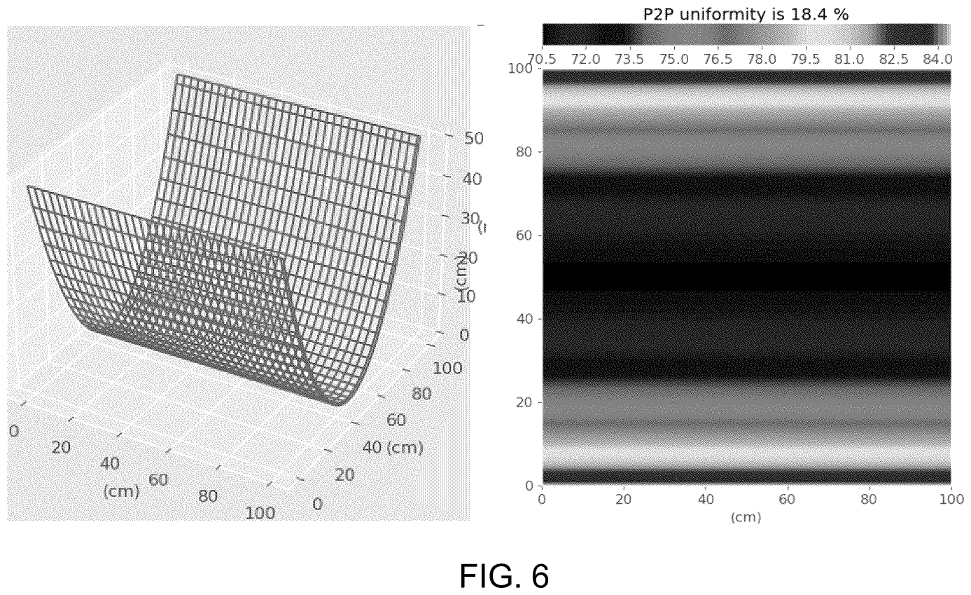

FIG. 5 and FIG. 6 show the same curved substrates and corresponding simulations results for the deposition layer thickness by the same inline coater as in FIG. 2 and FIG. 3, except for 90°-rotated substrates relative to the sputter source. In consequence, the depicted substrate surfaces are oriented such that their (only) principal direction is aligned parallelly with the length axis of the sputter target and perpendicularly to the substrate transport direction. At present, the average thickness non-uniformity along the direction of the target axis predominates in the overall thickness non-uniformity distribution, whereas no substantial thickness variation is observed along the substrate transport direction. More specifically, the simulated average thickness of the sputter-deposited layer along the second direction varies between −20.0/+7.9% for the example substrate in FIG. 5 and between −6.0/+12.4% for the example substrate in FIG. 6. The respective values of the peak-two-peak thickness non-uniformity are 27.9% and 18.4%.

FIG. 7 presents simulation results for deposited layer thickness of the same substrate as shown in FIG. 6, but applying a modulation technique to the magnetic field strength along the racetrack of the inline coater. Contrary to the situation of FIG. 3, planes with normal direction parallel to target length axis now intersect the substrate along straight lines whose points are substantially equally spaced with respect to the sputter target by the time they pass underneath the sputter source. However, planes with normal direction parallel to the substrate transport direction intersect the substrate along curves whose points have different spacings relative to the sputter target by the time they pass underneath the sputter source. Hence, the distance between the sputter source and the curved surface of the moving substrate does not change significantly over time but is a function of position along the length of the target. This effect can be compensated by magnet bar tuning inside the sputter source such that a position-dependent magnetic field strength is obtained along the length direction of the sputter target. Points on the substrate surface that are further away from the sputter target surface require stronger magnetic fields than points on the substrate surface that are located closer to the sputter target surface. Magnet bar tuning can efficiently reduce the large variations in the deposited layer thickness observed in FIG. 6, but has limited resolution and is relatively slow, e.g. in comparison to electrical power supply modulation techniques for the sputter target. The simulated peak-to-peak thickness non-uniformity in FIG. 7 is now limited to 1.8%.

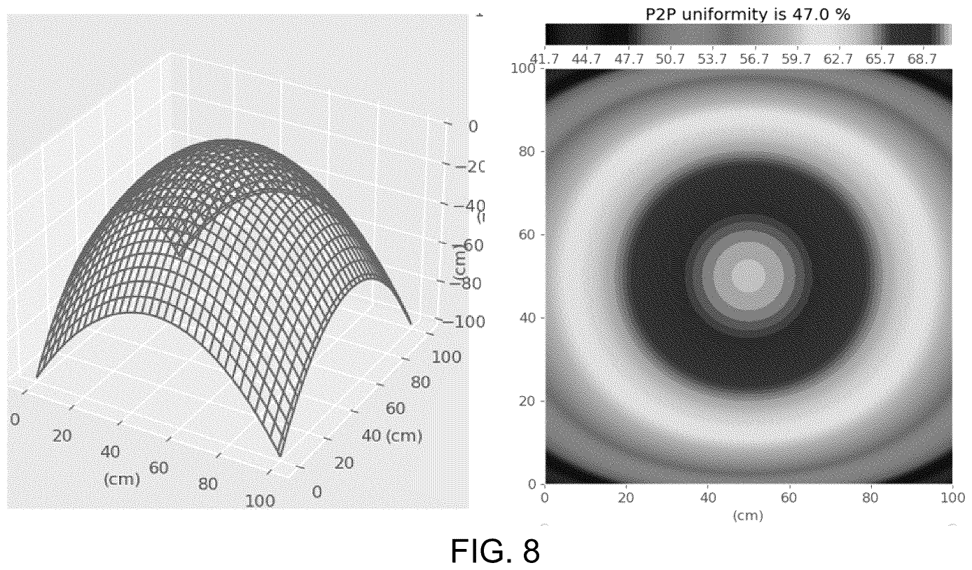

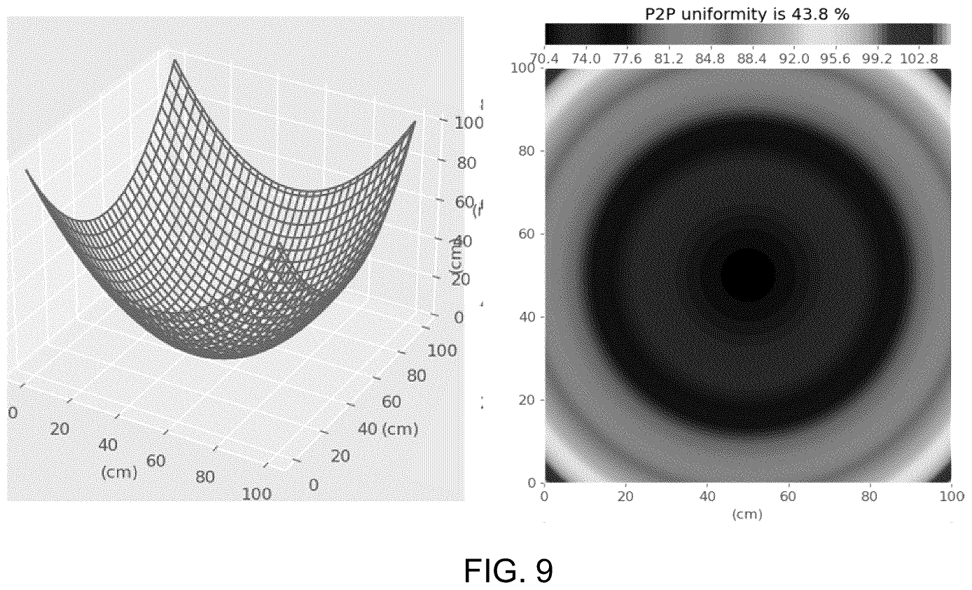

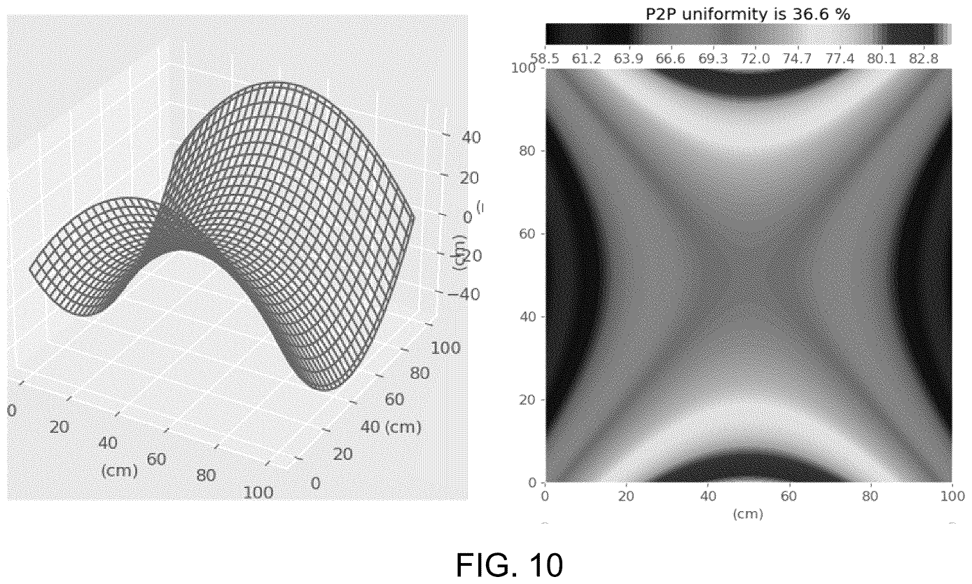

FIG. 8 to FIG. 11 are further examples of 1.0 ×1.0 m sized, curved substrates and corresponding simulations results for the deposition layer thickness by the same inline coater, but having curvature components both along the first direction and along the second direction. The corresponding values of the peak-to-peak thickness non-uniformity are, in ascendent order of the figure numbers, 47.0%, 43.8%, 36.6% and 44.8%. It can be seen that a second curvature component further exacerbate the thickness variations of the deposited layer, demanding even more sophisticated compensation techniques.

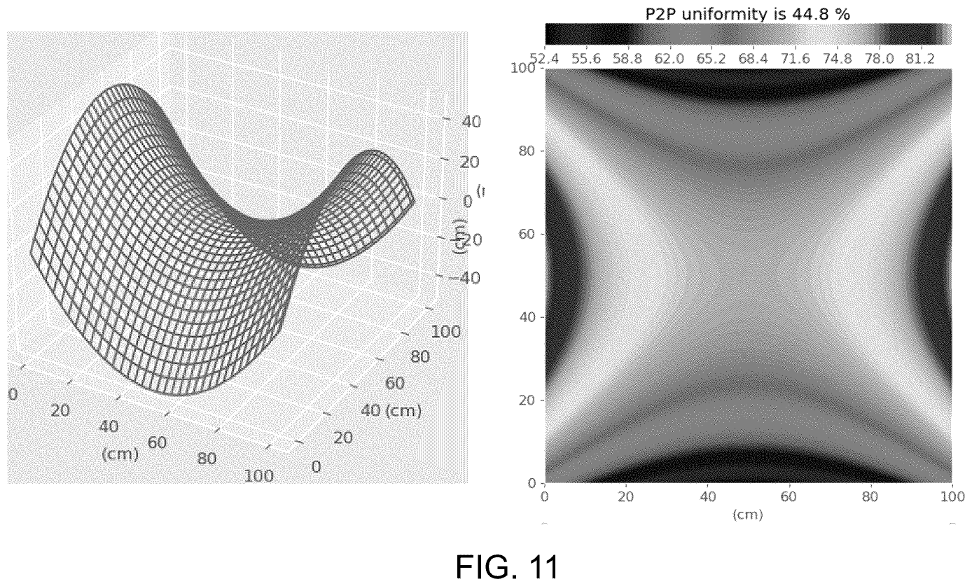

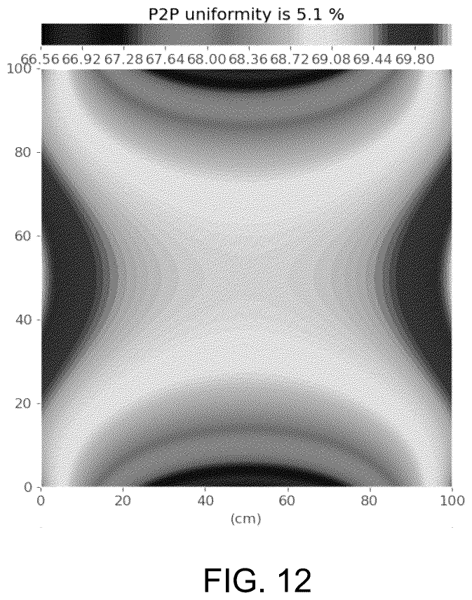

One approach is to combine the two previously presented compensation techniques for the different curvature directions, which results in a bidirectional tuning method. FIG. 12 shows simulation results for deposited layer thickness of the substrate in FIG. 11, when bidirectional tuning is applied to the inline coater, i.e. the simultaneous and synchronized modulation of electrical power supply to the sputter target, substrate transport speed and localized magnet bar deformation. This allows the simulated peak-to-peak thickness non-uniformity to be as low as 5.1%.

Another situation in which the bidirectional tuning method may be needed, correspond to substrates with a single principal curvature direction that are transported in a direction that forms an angle with the principal curvature direction, i.e. is not aligned with the principal curvature direction. This is the case, for example, of the curved substrates shown in FIG. 2-3 or FIG. 5-6 after a rotation by 45° about the height axis (third direction), or by any other angle that does not result in aligned directions of the principal curvature and the substrate transport. It is also case for substrates whose principal curvature direction is oblique with respect to the first and second direction, but which cannot easily be rotated, e.g., due to restrictions of the substrate handling system, the dimensions of the substrate transport system, the dimensions of the sputter process chamber, etc.

Although acceptable from a theoretical point of view, this bidirectional tuning solution is less appealing in practice. It would involve complex control algorithms in interplay with tuning systems that have to be precisely synchronized with the position and motion of the substrate relative to the sputter source, which are less robust and prone to unexpected deviations. Moreover, it would necessitate the use of sputter targets that have a specific, substrate shape-dependent thickness profile along the target length to counter the effect of a non-uniform target erosion profile forming along the length axis of the sputter target as a result of the magnetic field strength tuning.

In a first aspect, the present invention provides a solution to the problem of non-uniform target erosion and overly complex and error-prone control algorithms for inline magnetron sputter coating processes in which the surface or surface portion of a substrate to be coated has curvature components along each one of two orthogonal directions that coincide with the substrate transport direction and the length axis of the cylindrical sputter target, respectively. This includes substrate surfaces or surface portions for which the direction of principal curvature neither coincides with the substrate transport direction, nor with the length axis of the cylindrical sputter target. In this case, the principal curvature direction has non-zero projections onto both the substrate transport direction and the length axis of the cylindrical sputter target. Substrate surfaces or surface portions whose shape varies in discrete steps, e.g. in which a discrete approximation to the principal curvature direction can be defined, are also encompassed.

A back surface of the substrate to be coated does not need to be curved, i.e. can be flat. Sharp or obtuse angles, e.g. edges, between otherwise flat, but possibly inclined surface portions of the substrate are considered surfaces with localized infinite curvatures and also fall under the scope of the present invention. Examples are multi-facetted surfaces or meshed created from a collection of triangles, quadrilaterals or the like, which may approximate a smooth surface.

The present invention also provides a solution to the problem of non-uniform target erosion and overly complex and error-prone control algorithms for inline magnetron sputter coating processes in which the surface normal (vector) to the surface or surface portion of a substrate to be coated has (vector) components along each one of two orthogonal directions that coincide with the substrate transport direction and the length axis of the cylindrical sputter target, respectively. This includes flat or curved substrates that have a sloping surface with respect to a base plane that spanned by the two orthogonal vectors along the substrate transport direction and the length axis of the cylindrical sputter target, respectively. Examples are flat substrates that are mounted onto a slanted carrier or slanted support member during transport, conical or cylindrical sections that have the form of ellipses, or others.

Further, the present invention provides a solution to the problem of non-uniform target erosion and overly complex and error-prone control algorithms for inline magnetron sputter coating processes in which a substrate surface or surface portion has to be coated with a material layer that has a thickness gradient in a direction that neither coincides with the substrate transport direction, nor with the length axis of the cylindrical sputter target, or requiring a thickness gradient in the second direction and varying along the substrate transport direction.

An assembly for use in a magnetron sputter apparatus, e.g. a magnetron assembly, according to the first aspect of the present invention comprises a first support member a second support member for mounting thereon an elongated, hollow sputter target and a magnet assembly, respectively. The assembly further comprises a first drive means configured to impart rotary motion to the first support member and an independent second drive means configured to impart rotary motion to the second support member, separately from the rotary motion imparted to the first support member. The axes of rotation of the first and second support member are parallel and may be substantially coaxial, in this case defining a common rotation axis. The magnet assembly comprises a magnetic structure that extends longitudinally along the common rotation axis and defines a closed-loop plasma confinement region under sputtering conditions of the magnetron sputter apparatus. A central portion of the magnetic structure, terminated by respective end portions of the magnetic structure, has a varying azimuthal position relative to the common rotation axis. Expressed differently, the azimuthal position of the central portion is not constant, but changes between the respective end portions of the magnetic structure. This causes a material flux of sputtered particles leaving the surface of the sputter target under sputtering conditions that is (i) non-uniform along the length axis of the sputter target and (ii) dependent on the rotary motion of the magnet assembly mounted on the second support member.

End portions of the magnet assembly, in the context of the present disclosure, are understood as those portions that limit the extent of the magnet assembly in the longitudinal direction, i.e. along the axis of elongation of the elongated magnet assembly. End portions of the magnet assembly correspond to end portions of the hollow sputter target when the latter is mounted over the magnet assembly such that it surrounds and encloses the magnet assembly in a radial direction (i.e. direction perpendicular to the axis of rotation associated with the magnet assembly). In consequence, end portions of the magnetic racetrack and end portions of the plasma racetrack induced by the magnet assembly are defined by the end portion of the magnet assembly and have similar longitudinal locations (e.g. coordinates along the axis of rotation associated with the magnet assembly). An end turn of the magnetic or plasma racetrack is thus understood as a turn of a closed-loop path that is situated at one of the two limit points of the racetrack, e.g. the farthest points of the racetrack that limit the racetrack's extent in the direction parallel to the rotation axis of the magnet assembly.

In embodiments of the invention, the sputter target is a rotary target. It is generally shaped as an elongated hollow body of revolution, which can have differently shaped inner and outer surfaces extending along the axis of elongation. In some embodiments of the invention, the sputter target has a cylindrical or nearly cylindrical outer surface of revolution, thus generating a tubular sputter target. For instance, the inner and outer surface of revolution are separated by a fixed distance in the radial direction, perpendicular to the axis of revolution, resulting in a hollow cylinder with fixed inner and outer diameter. Another example is that of cylindrical inner surface with fixed inner diameter (i.e. generated by revolving a straight line parallel to the axis of revolution) and an outer surface of revolution of the sputter target that has a varying outer diameter, e.g. an outer diameter that is constant in a central portion of the sputter target but widens towards or at the end portions of the sputter target. Outer surfaces of revolution in the shape of a dog bone or a dumbbell are examples of outer surfaces that have a varying outer diameter. Advantageously, such widened end portions of the sputter target partially or completely offset an increase in the target erosion (end grooving) that is mainly due to the turnaround sections of the plasma racetrack (change in plasma density and longer dwell times of target material under plasma bombardment) adjacent to these end portions under sputtering conditions. The widened sections of the target may be the result of a thicker sputter material inventory in these sections, which is applied to a cylindrical outer diameter backing tube, or the result of a shaped backing tube, e.g. a backing tube comprising non-consumable collars welded onto sections for which the widening is desired, e.g. end sections of an otherwise straight backing tube. The sputter material thickness may be uniform on shaped backing tubes, or may have a variable thickness (but constant outer diameter, for instance).

In embodiments of the invention, the material flux of sputtered particles is thus dependent on the rotary motion of the magnet assembly about the rotation axis of the second support member (i.e. rotation axis of the magnet assembly) and non-uniform along normal projections of the rotation axis onto planes that are parallel to the rotation axis and distant to the magnet assembly. A shape of the magnetic structure may be configured to cause, at least for a sub-range of admitted rotation angles of the magnet assembly, a substantial difference in material flux of sputtered particles along the projected rotation axis during sputtering, and/or may cause a substantial change in material flux of sputtered particles along the projected rotation axis when rotating the magnet assembly during sputtering. In other words, shape of the magnetic structure may be configured to cause a position-dependent sputter flux along the direction of the rotation axis of the second support member for at least one rotation angle of the magnet assembly, and preferably for an extended range of rotation angle, e.g. all or almost all admitted rotation angles for which sputtering onto a moving substrate occurs. In consequence, a position-dependent sputter flux is also observable along the target length axis of a mounted target, leading to a position-dependent sputter flux across the width dimension of the substrate, e.g. at any given moment in time while the substrate is being coated. Additionally, the position-dependent sputter flux that is caused by the specifically adapted shape of the magnetic structure along the direction of the rotation axis of the magnet assembly is also time-dependent under a rotary motion of the magnet assembly. This leads to space-time-dependent sputter flux across the width dimension of a static substrate, which translates into a position-dependent sputter flux across the length dimension of a moving substrate.

In embodiments of the invention, shape of the magnetic structure may be configured to cause a substantial difference in the preferential or dominant sputtering direction of target material along the direction of the rotation axis of the magnet assembly, and this preferential sputtering direction evolves in time as the magnet assembly is rotated.

A variation in the azimuthal position of the magnetic structure along the central portion may be at least 20°, e.g. at least 30°, e.g. 40° or more, e.g. 70° or more, e.g. 90° or more, e.g. 180° or more, e.g. up to 360°, in either direction, i.e. positive or negative angular excursions. Hence, there may be two distinct points in the central portion of the magnetic structure whose associated azimuthal coordinates with respect to the rotation axis of the magnet assembly differ by at least 20°, e.g. at least 30°, e.g. 40° or more, e.g. up to 70° or more, e.g. 90° or more, e.g. 180° or more, e.g. up to 360°, in either direction. A full 360° angular variation in the azimuthal position of the magnetic structure corresponds to a winding of the magnetic structure about its axis of rotation, e.g. the winding of a magnetic path or track thereof on the outer circumferential surface of a support tube. The full 360° angular variation in the azimuthal position of the magnetic structure, if the winding is helical in nature, also allows the definition of a pitch as the axial/longitudinal separation of two point of the magnetic structure whose azimuthal coordinate differ by 360° (full turn). The azimuthal position of the magnetic structure may be the azimuthal coordinate of at least one of its magnetic components such as one of its magnetic rows, magnetic tracks, magnetic arrays, legs or magnetic paths. Alternatively, the azimuthal position of the magnetic structure may be identified as the azimuthal coordinate of one its associated magnetic pole lines.

The first and second support members may be mounting flanges or end plates. They may be comprised by an end block. At least one end block may comprise the first and second drive means, e.g. a single end block comprises both the first and second drive means or two opposite end blocks may each contain a respective one of the first and second drive means.

A radial position of the magnetic structure may be adjustable either globally through a radially inward or radially outward displacement of a magnetic support structure, or locally through deformations of the magnetic support structure at well-defined locations along the common rotation axis.

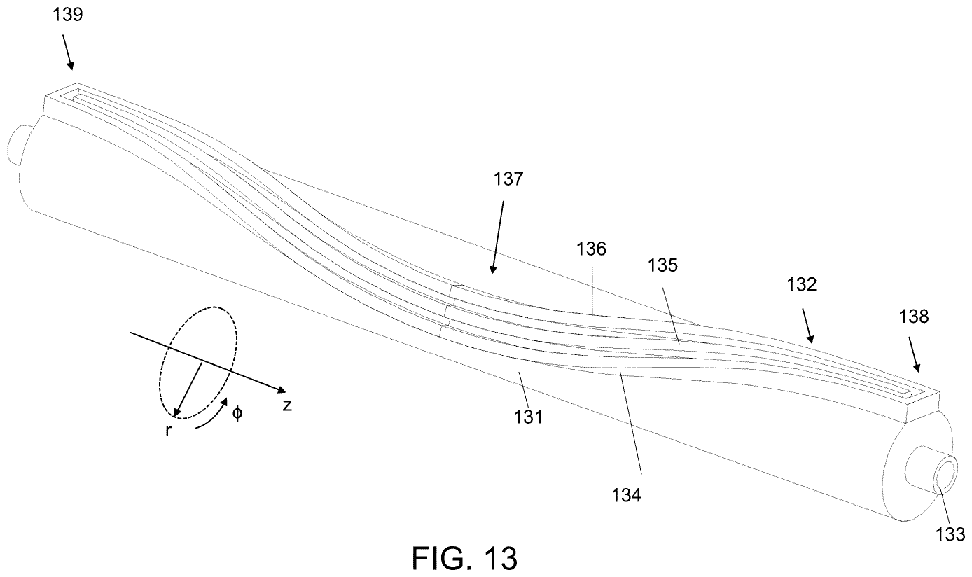

FIG. 13 is a perspective view of a magnet assembly 130 in accordance with embodiments of the invention. The magnet assembly takes the form of an elongated magnet bar 131, which is tubular in shape (e.g. hollow cylinder) and is slid over and firmly attached to a hollow support tube 133. Alternatively, the magnet bar may be formed directly on the support tube 133 or be an integral part of a patterned support tube. The magnet bar acts as a pole piece for three magnetic tracks or rows 134-136 that project or protrude radially outwards (i.e. in the radial direction ‘r’) from an outer surface of the magnet bar 131. It connects the magnetic poles of adjacent rows 134-136 that face the magnet bar 131 or are in contact with the magnet bar 131. Therefore, the magnetic flux is concentrated in the magnet bar 131 in the radial inwards oriented portion of the magnet assembly. The magnet bar may be formed from a soft iron or other magnetic permeable material (e.g. Nickel, Cobalt, etc.). The three magnetic tracks are elongated magnetic components that extend in a longitudinal direction ‘z’. Each track may be formed from a special-shape permanent magnet (e.g. soft iron) or assembled from a plurality/array of individual permanent magnets or magnetic segments that are aligned into a chain-like structure and follow a specific path, e.g. a parametrized curve that describes the azimuthal coordinate of one or more magnetic track, e.g. each magnetic track, along the length of the track, e.g. as a function of longitudinal distance ‘z’: φ=φ(z). Magnetic poles of individual but aligned magnets along the same track are oriented in the same direction, e.g. all north poles or all south poles pointing radially outwards. The permanent magnets of each track may be rare-earth magnets. A central track 135 is arranged between two peripheral or side tracks 134, 136. For instance, an equidistant spacing between the central track and each of the two side tracks may be chosen. The radially outwards oriented magnetic pole(s) associated with adjacent tracks alternate, e.g. radially outwards pointing south pole for track 134, radially outwards pointing north pole for track 135, and radially outwards pointing south pole for track 136. End portions 138 and 139 connect the two side tracks 134, 136 at each extremity of the longitudinally extending magnetic structure 132, thereby establishing a closed-loop magnetic racetrack for the magnetic pole lines associated with the side tracks. This in turn induces a closed-loop plasma racetrack in a magnetron assembly, which uses the magnet assembly 130, under sputtering conditions. In this example, the end portion 138, 139 are turnaround sections of the magnetic structure that are angled (e.g. right angles). End portions may be shaped differently in other embodiments of the invention, e.g. as rounded turnarounds. The radial outwards oriented end portions of the magnetic tracks 134-136 may be profiled to conform to the circular shape of the interior wall of a cylindrical target or magnet assembly enclosure. Indentations, which may be formed with an angle or sloping bottom surface, may be provided as seats for the individual magnets along each track. In embodiments of the invention, the azimuthal position ‘φ’ of the magnetic structure 132, e.g. of at least one magnetic track or of the path followed by at least one magnetic component of the projecting magnetic structure, varies substantially between the respective end portions 138, 139. In the present embodiment, the magnetic structure 132 comprises a bulge 137 in its central portion, wherein the central portion lies between the respective end portions and comprises a region that is located midway between the end portions 138, 139 (measured along the longitudinal coordinate ‘z’).

The magnetic structures of the magnet assembly and the closed-loop plasma racetracks induced thereby extend longitudinally along the rotation axis of the magnet assembly, e.g. the common rotation axis defining the length direction of the sputter target. They usually extend over a substantial part of the target length, e.g. over the entire length or almost the entire length of the cylindrical target, and are longer than they are wide. In embodiments of the invention, the magnetic structures of the magnet assembly and the closed-loop plasma racetracks induced thereby may be asymmetric with respect to any plane containing the rotation axis of the magnet assembly. Additionally, the magnetic structures of the magnet assembly and the induced closed-loop plasma racetracks may lack symmetry with respect to planes perpendicular to the rotation axis, e.g. a central plane intersecting the magnetic structure midway between its extreme points on the respective turnaround/end portions and/or intersecting the cylindrical target midway between its end faces. Preferably, the magnetic structure induces only a single closed-loop plasma racetrack over the target surface during sputtering operation. The closed-loop racetrack generally consists of two different elongated paths that extend in the length direction of the magnet assembly and are connected by two distinct end segments towards either end of the magnet assembly: the turnaround portions. For a mounted target under sputtering conditions, the turnaround portions of the plasma racetrack are generated over respective end portions of the target surface. A magnetic racetrack corresponding to the plasma racetrack can be defined as the closed-loop contour line at a predefined radial distance to the rotation axis of the magnet assembly (e.g. at the target surface) along which the tangential component of the magnetic field generated by the magnetic structure is maximal.

An azimuthal position (angular position, angular coordinate) of portions of the magnetic structure is best defined through the corresponding azimuthal position of the induced plasma racetrack, always considered locally at a specific point on the rotation axis of the magnet assembly. In other words, a cylindrical coordinate system whose longitudinal/cylindrical axis is coaxial with the rotation axis can be used to define the azimuthal, radial and axial position (φ, r, z) of the plasma racetrack or the underlying magnetic structure. In most embodiments of the invention, a constant radial position of the plasma racetrack is preferred, except in the case if the target tube may be exhibiting some topography (e.g. static topographical feature, such as shaped backing tube or profiled sputter material thickness on backing tube, or dynamic topographical feature, i.e., as formed during use, e.g. due to non-uniform target erosion). The (local) azimuthal position ‘φ’ of the plasma racetrack is then a function of the axial/longitudinal coordinate alone, i.e. φ=φ(z). This functional relationship may also be applied to target tubes with radially symmetric topography. Alternatively, the azimuthal position of portions of the magnetic structure may be defined via the local orientation of one of its radially outwards oriented magnetic poles that are facing the interior wall of the cylindrical target, or if the magnetic structure is composed of one or more arrays of magnets, via the local orientation of lines or curves that connect the radially outwards oriented magnetic poles of neighboring magnets belonging to the same array. The magnetic poles may be the poles of permanent magnets or the induced poles of pole pieces that redirect and shape the magnetic field generated by the magnetic structure. While the shape of the plasma racetrack is defined by a continuous and, in most cases, a smooth path, the underlying magnetic structure for inducing the plasma racetrack may be partly non-smooth, e.g. comprise sharp turns, kinks, or the like.

According to embodiments of the invention, the azimuthal position of the central portion of the magnetic structure varies, i.e. is non-constant, between its end portions. Here, the end portions of the magnetic structure are those portions that terminate the magnetic structure in the direction of the common rotation axis. End portions of the magnetic structure are often shapes as 180°-turns, e.g. U-turns or variations thereof, and are located at or near corresponding end portions of the cylindrical target. The azimuthal position of the central portion of the magnetic structure may vary globally, e.g. vary continuously or in steps between the end portions and this over a substantial part of the target length. The azimuthal position of the central portion of the magnetic structure may vary linearly between the end portions, or may follow a curvilinear path. For instance, the azimuthal position of the central portion of the magnetic structure may vary according to a second-order or higher order curve φ=φ(z), or any other (multi-valued) function. The azimuthal position of the central portion of the magnetic structure may be varied in such a way that the magnetic structure and the plasma racetrack induced thereby comprises at least one bulge, turn, wrinkle or fold. In embodiments of the invention, the azimuthal position may be varied in such a way that the magnetic structure and the plasma racetrack induced thereby are not parallel to the common rotation axis over a substantial part of their length. Furthermore, the azimuthal position may be varied in such a way that the magnetic structure and the plasma racetrack induced thereby are curved in the middle part, e.g. midway between the end portions of the magnetic structure. In some embodiments of the invention, the central portion may be connected to the end portions by means of a transition region. Angular offsets or discontinuities between the central portion and the end portions may be levelled out by the transition region. When reference is made to the curvature, the path direction or tangents to the shape or contour of the plasma racetrack, or the magnetic structure underlying and inducing the racetrack, these quantities refer to a parametrized curve φ=φ(s) that describes the azimuthal position of the plasma/magnetic racetrack as a function of position parameter ‘s’ along the curve, e.g. describing the azimuthal position of a forward path, a return path, or both along the central portion of the plasma/magnetic racetrack. A straight path is a path with zero curvature. Common choices for the position parameter ‘s’ include the axial position ‘z’ along the rotation axis of the magnet assembly or the arc length associated with the plasma/magnetic racetrack. Hereinunder, the forward path and return path are also referred to as ‘legs’ of the plasma/magnetic racetrack.

Above considerations of variations in the azimuthal position of the magnetic structure and the thereby induced plasma racetrack apply to at least one of the legs or paths that connect the respective end portions of the magnetic structure, e.g. applies to one or both of the legs. In some embodiments of the invention, the variations in the azimuthal position of the magnetic structure and the thereby induced plasma racetrack applies to only one of the two legs (e.g. intermediate sections between the respective end portions), whereas the other leg is substantially straight. Straight legs have the advantage that they are easier to manufacture. In other embodiments of the invention, the variations in the azimuthal position of the magnetic structure and the thereby induced plasma racetrack applies to both legs in unison. This results in a central portion in which the azimuthal position of one leg is tied to the azimuthal position of the other leg and the two legs are substantially equidistant to each other. Equidistant legs have the advantage that larger magnitudes for the combined material flux of sputtered particles can be obtained and controlled by the distance value between the two legs. In yet other embodiments of the invention, the variations in the azimuthal position of the magnetic structure and the thereby induced plasma racetrack applies to both legs independently; the two legs are thus not necessarily equidistant to each other. Embodiments of this kind have the advantage of more design flexibility.

According to some embodiments of the invention, the amount of variation in the azimuthal position (angular change) of the magnetic structure, e.g. the azimuthal position of one or both legs of the magnetic structure, is at least 20°across the central portion between the end portions of the magnetic structure. In other words, the azimuthal position of the magnetic structure (e.g. a leg thereof) at one point on the common rotation axis differs by at least 20°, e.g. between 20° and 40°, or even 40° and above, from the azimuthal position of the magnetic structure at another point on the common rotation axis, provided that both points belong to the central portion of the magnetic structure. This variation may be in either or both directions, e.g. a positive angular change of at least+20°, a negative angular change of at least−20°, or a positive angular change of at least+20° followed by a negative angular change, or vice versa.

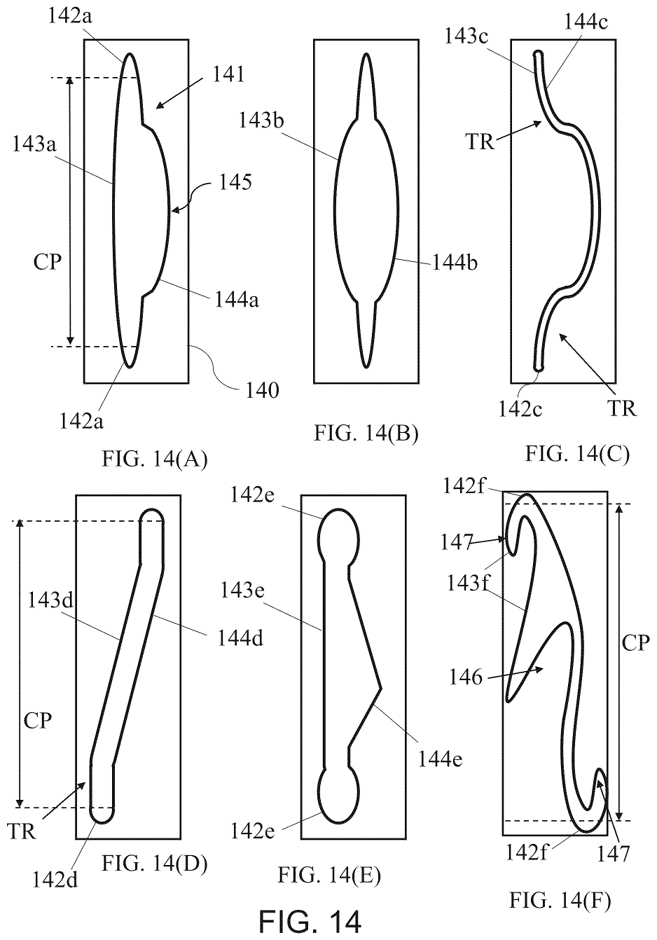

FIG. 14 illustrates various shapes of elongated closed-loop plasma racetrack that can be induced by a magnet assembly in accordance with embodiments of the invention. In general, the shape of the plasma racetrack follows the shape of the underlying magnet assembly, e.g. the lines, tracks or contours associated with one or more of the magnetic poles of the magnet assembly that are facing the inner wall of a target tube with the target material.

The single closed-loop racetrack 141 shown in FIG. 14(A) is induced adjacent to the outer surface of a cylindrical hollow sputter target 140. The magnetic field lines generated by an elongated magnetic structure (not shown) rotatable mounted inside the hollow target tube target traverse the target tube wall. The racetrack 141 comprises a central portion ‘CP’ which is terminated by two opposite end portions 142a. The azimuthal position of the two legs 143a, 144a is varied independently between the respective end portions 142a. The first leg 143a is only slightly curved, whereas the second leg 144a comprises a bulged region 145 of stronger curvature. The two legs 143a, 114a are not formed equidistantly and the racetrack 141 is asymmetric with respect to any plane containing the cylindrical axis of the target tube 140.

The single closed-loop plasma racetrack shown in FIG. 14(B) has a left-right mirror symmetry. The mirror plane contains the cylindrical axis of the target tube and the two extreme points of the racetrack along the length direction of the cylindrical target tube. The azimuthal position of the two legs 143b, 144b changes in opposite directions between respective end portions of the plasma racetrack. Bulged regions of each of the two legs 143b, 144b are opposing each other.

In the exemplary racetrack shown in FIG. 14(C), the two legs 143c and 144c are formed equidistantly. Their azimuthal direction is thus varied in unison between the respective end portion 142c. A common bulge is formed by the two legs along the central portion. In contrast to the preceding racetracks, the first leg 143c has a concave contour. The two end portions 142c have substantially equal azimuthal coordinates, but the path direction (tangents to the legs) near the end portions does not match the path direction on both ends of the central bulge. Transition region ‘TR’bridge the difference in path direction and provide a smooth change of curvature.

The racetrack of FIG. 14(D) also has equidistant legs 143d, 144d but differs from the racetrack example in FIG. 14(C) in that both legs have zero curvature, i.e. their respective angular positions are linear functions of the axial coordinate ‘z’ in the central portion ‘CP’. This results in an angular offset in the positions of the two end portions 142d. Transition regions ‘TR’ compensate for the difference in the sloping angle ∂φ/∂z. The exemplary, but non-limiting racetrack configuration of FIG. 14(D) provides a good solution to the problem of how to gradually increase the deposition rate in a specific zone across the substrate and sustain this distribution along the substrate in the movement direction. A bigger azimuthal shift between the end portions (top and bottom) causes a sharpening and narrowing of the localized zone of extra deposition, whereas a smaller azimuthal shift causes a blurring and widening of the localized zone of extra deposition. Turning the magnet assembly, e.g. the magnet bar, displaces the zone of extra deposition across the substrate. In variants of the exemplary racetrack shown in FIG. 14(D), the transition regions ‘TR’ are absent and/or the angular offset in the positions of the two end portions is much larger. For instance, the two equidistant legs of the plasma racetrack wind around the outer surface of the hollow sputter target by 180° or more, e.g. by 360° or more. The angular offset in the positions of the two end portions then amounts to 180°and 360°, respectively. In the former case, the two end portions are located at diametrically opposite sides (e.g. front and back) of the target circumference, whereas in the latter case, the two end portions are located at the same side of the target circumference (e.g. both front).

In contrast to all the preceding racetrack examples A-D, the racetrack of FIG. 14(E) also lacks symmetry with respect to mirror plane that is perpendicular to the longitudinal axis of the hollow target cylinder. Leg 143e is substantially straight, i.e. has a fixed angular position along the length of the cylindrical target, while the azimuthal position of the second leg 144e is linearly increasing in the beginning of the central portion and linearly decreasing thereafter. The change in direction of the azimuthal coordinate is smooth but rather abrupt in this example. The end portions 142e are formed with a spoon-like shape, e.g. are locally widened. This has the advantage that the faster target erosion and groove formation that is observed near the end portions of conventional rotary sputter targets can be reduced.

The racetrack of FIG. 14(F) has the particularity that its respective end portions 142f are connected to hooks 147 in the central portion and the central portion comprises a first leg or forwards path 143f with a fold, whereby a pouch or pocket region 146 is formed. In this pouch-like region of the central portion of the racetrack, the function φ(z) for the leg 143f is multi-valued and consists of several branches. Similarly, the function φ(z) is multi-valued and consists of several branches in the hook regions 147. A change of parametrization, e.g. towards arc length, can remove the multi-valuedness. For the particular racetrack shown, a higher sputter yield is obtained in the folded regions (hooks, pouches) of the racetrack. This is advantageous in sputter processes which require an intense localized material flux. To compensate for the accelerated target erosion (extra dwell time of target material under plasma conditions) and achieve good overall target utilization, the sputter target may be equipped with additional sputter material in the specific regions corresponding to the folded regions of the racetrack. Contrary to all the preceding racetrack examples A-E, a plane perpendicular to the rotation axis of the magnet assembly intersects the racetrack of FIG. 14(F) in more than two points, e.g. three or four points.

Shapes of the magnet assembly, e.g. the magnetic pole lines, tracks or contours associated with at least one of the magnetic poles, and the thereby induced closed-loop plasma racetrack are not limited to the preceding examples. Other shapes may be adopted, e.g. shape contours resembling the shape of a boomerang, a crescent, a banana, an elongated S-shape, an hour glass, etc. The shapes or contours may be defined—piecewise or globally—by splines, Bézier curves or other type of mathematical curves, e.g. conchoids, cissoids, bicorne (cocked hat curve), hippopedes, Cassini ovals, inverted nephroid, or cubic, quartic or higher-order non-intersecting plane curves.

In some embodiments of the invention, a plane containing the rotation axis of the magnet assembly may intersect the central portion of the magnetic structure in at most four points, e.g. in four points or in two points. The azimuthal position of the magnetic structure may vary throughout a substantial fraction of the central portion, e.g. over the entirety of the central portion. Furthermore, the azimuthal position in the middle of the magnetic structure, i.e. mid-way between the respective end portions, may be different from the azimuthal position of the magnetic structure where the end portions connect to the central portion. The azimuthal position of the magnetic structure may include at least one inflection point, e.g. one, two, or more inflection points in the central portion.

A variation in the azimuthal position of the magnetic structure along its central portion causes a corresponding tilt angle in the forward and/or return path of the closed-loop plasma racetrack, which is dependent on the path's axial coordinate along the common rotation axis. Varying the azimuthal position of the central portion of the magnetic structure between the end portions of the magnetic structure in accordance with embodiments of the invention, thus has the effect that material flux of sputtered particles leaving the target under operating conditions has an azimuthal (direction) component that varies along the length direction of the target. It is therefore possible to tailor the deposition rate and film thickness in the longitudinal direction of the target (corresponding to width dimension of the substrate). Thickness control of the deposited film along the substrate width can be combined with the above described methods for thickness control of the deposited film along the substrate length, e.g. controlling the instantaneous transport speed relative to the stationary sputter target and/or controlling the electrical power that is applied to the target as a function of substrate position relative to the stationary sputter target. Moreover, magnet bar tuning techniques for the local adjustment of the magnetic field strength along the length direction of the target can be used in addition to the varying azimuthal position of the central portion of the magnetic structure to further improve, fine-tune or compensate for the impact of target erosion on the thickness uniformity of the deposited film along the substrate width.

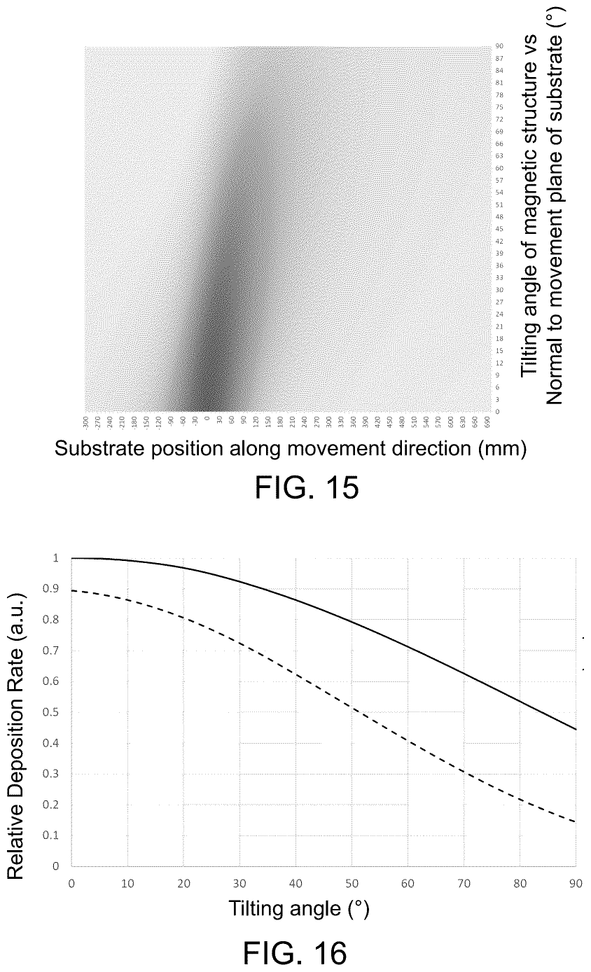

FIG. 15 and FIG. 16 show the calculated dependences of the deposition profile and the normalized deposition rate on the tilt angle (i.e. rotation angle) of the magnetic structure, respectively. The magnetic structure is tilted inside the hollow target tube, thus changing the angle between the preferential sputtering direction and a substrate-normal direction. In other words, the magnet assembly is rotated toward different tilt angles relative to a reference angle at 0°, where the magnetic structure is oriented in a direction perpendicular to the substrate (transport) plane to face the substrate at minimal separation distance to the sputter source. The calculated dependences may be useful in methods for designing and manufacturing the shape of the central portion of the magnetic structure and in methods for controlling the sputter process of non-planar substrates, e.g. via the rotary motion of the magnet assembly to different tilt angles.

More specifically, a 2D map is shown in FIG. 15 which describes the mutual dependence of the deposition profile (more deposition corresponding to darker shading and less deposition corresponding to lighter shading) on substrate position relative to the target (x-axis) and the angular position increment (tilt angle) of the magnetic structure relative to its reference angle (y-axis). Deposition is onto a flat stationary substrate under a single cylindrical target. The substrate is positioned at the origin if it is located exactly under the length axis of the target (perpendicular projection of the rotation axis). A typical substrate to target spacing distance of 90 mm has been used for this simulation. As expected, introducing a tilting angle away from the normal position (reference angle at 0°) directs the material flux to a different position on the substrate and the material density is reduced as well. Furthermore, the tilting introduces a tail of low material flux deposition further away on the substrate.

FIG. 16 represents the relative deposition rate as a function of the rotation angle of the magnetic structure. The plotted deposition rate accounts for the integral amount of sputtered material that is collected by the substrate along the movement direction and for a given tilting angle away from the normal direction towards the substrate. The solid line represents an ideal case where no shielding effects occur in the coater and most of the sputtered material is collected somewhere on the substrate. The relative deposition rate is normalized for the case without shielding and for perpendicular exposure of the substrate. Upon introduction of tilting, the amount of material arriving at the substrate is reduced. At 90° tilting angles, the simulation shows that only about 45% of the sputtered material still lands on the substrate. More realistic magnetrons are positioned in compact compartments and shields may be present between the substrate and the cylindrical target tube. Vertical lines can be drawn on the 2D map of FIG. 15 to define the position of straight shields in the coating compartment between which the deposited material needs to be integrated, e.g. vertical lines at 31 240 mm and +240 mm, respectively. The dotted line in FIG. 16 corresponds to a shield opening of 480 mm that is symmetrical with respect to the cylindrical target. Even in the absence of tilting about 10% of the material will be collected on the shields. Introducing a tilting of the magnetic structure (i.e. the magnetron) leads to a more pronounced effect due to the shielding and also increase sensitivity of the relative deposition rate with respect to the tilt angle. At 90° tilt angles, the relative deposition rate is decreased by as much as a factor five in comparison to the case without tilting, losing almost all the sputtered material on the shields. Having an adjacent magnetron with the inverse inward tilting angle mitigates the material loss to some extent.

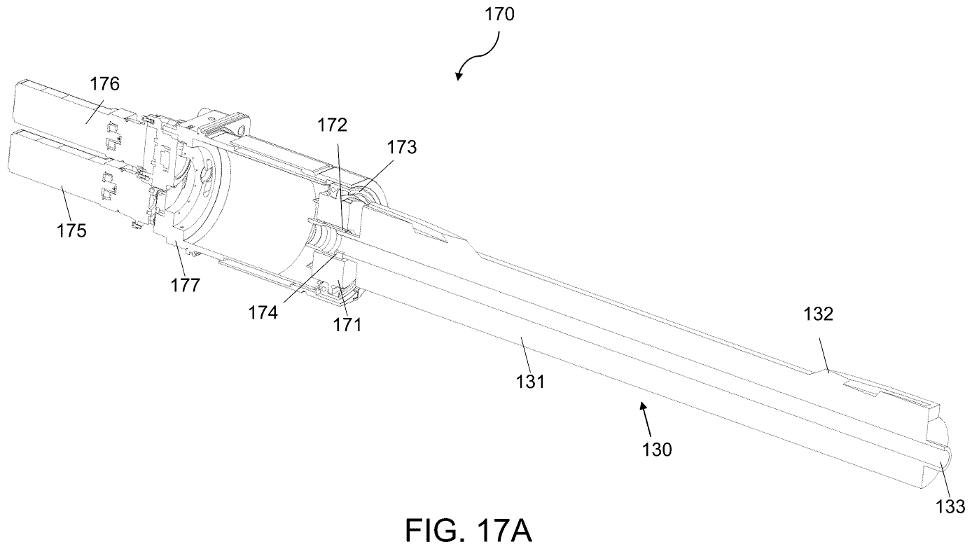

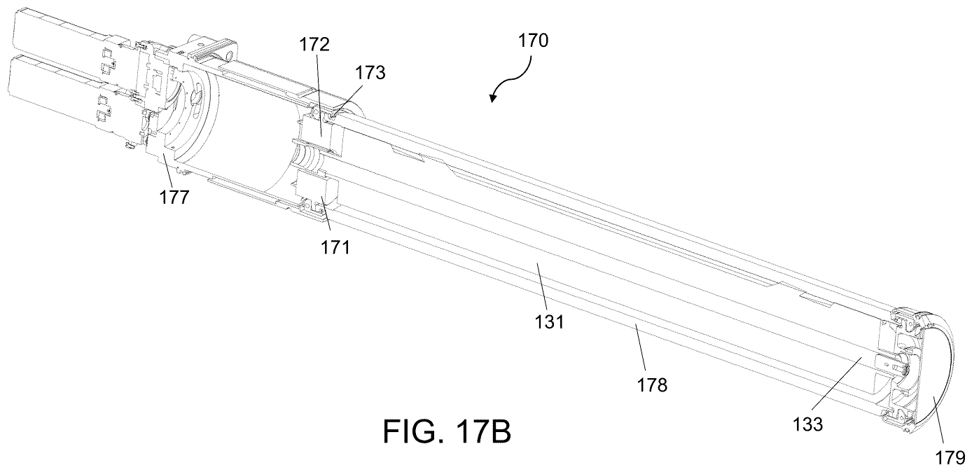

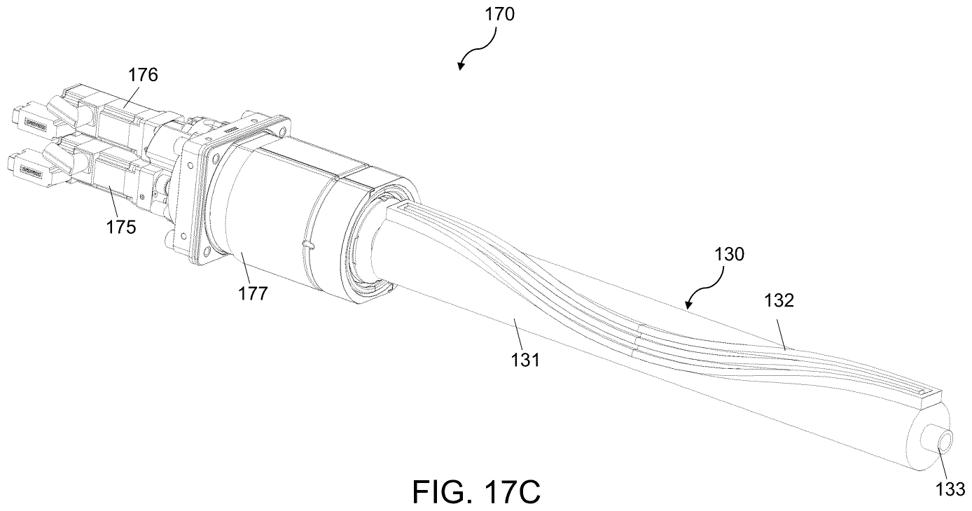

FIG. 17A is a cutaway view of a magnetron assembly according to an embodiment of the invention. The magnetron assembly 170 comprises an end block with end block housing 177 which can be mounted (e.g. side-mounted) onto a wall of a vacuum chamber. A rear portion of the end block housing carries two electrical motors 175, 176 as first and second drive means. This rear portion may be arranged outside the chamber wall, under atmospheric conditions. A middle portion of the end block is shown empty for ease of understanding, but generally contains various components such as, but not limited to, a power transfer means, a water collector, a bearing system for rotatable parts like drive shafts, sealing cassettes for vacuum and water, and force transmission systems with regard to the driving forces/torque generated by the two drive means 175, 176 (e.g. drive shafts or spindles, gear systems, etc.). A front portion of the end block typically extends into the vacuum of the chamber when the magnetron assembly 170 is mounted for use in a sputtering apparatus, e.g. an inline coater. The front portion comprises a first support member 171 in the shape of a rotatable hollow cylindrical mounting flange or thick annulus with a mounting flange, and a second support member 172 in the form of a widened end portion of a rotatable drive spindle. Rotation axes of the first and second support member 171, 172 are coaxial, defining a common rotation axis. A rotary motion of the first and second support member 171, 172 about the common rotation axis is generated by the first and second drive means 175, 176, respectively, and may be transmitted to the two support members via distinct drive shafts or drive spindles. The first support member 171 is adapted for receiving a tubular sputter target (not shown) and positioning it relative to the common rotation axis. A clamping structure 173 may secure the target in its mounted configuration. Similarly, the second support member 172 is adapted for receiving a magnet assembly 130 and positioning it relative to the common rotation axis. The magnet assembly shown in this figure is similar to the one described with reference to FIG. 13. In this example, the second support member 172 is provided with a central bore that is dimensioned to slidably receive a support tube 133 of the magnet assembly. A sliding key 174 facilitates the insertion of the support tube 133 into the central bore and prevents relative rotation between the second support member 172 and the support tube 133. The support tube 133 also serves the purpose of a fluid pathway for the coolant entering the magnetron assembly 170 (the coolant return path and end assembly cap are not shown). A gap between the outer surface of the second support member 172 and the inner surface of the first support member 171 may comprise a bearing or a lubricant, while guaranteeing that the rotary motions imparted on the first and second support member are mechanically decoupled.

FIG. 17B shows the same magnetron assembly as FIG. 17A with the addition of a cylindrical sputter target 178 mounted onto the first support member 171. Moreover, an end cap or end flange 179 is attached to the other end of the sputter target 178, distant to the end block, and redirects a coolant flow form the interior of the hollow support tube 133 to an annular gap region that is formed between the inner wall of the cylindrical target 178 and the outer surface of the magnet assembly 130 or a protective enclosure surrounding the magnet assembly 130. A protective enclosure around the magnet assembly 130 may be needed to avoid corrosion of the magnetic components of the magnet assembly by the colling liquid, e.g. water. In other embodiments of the invention, the magnetic components of the magnet assembly may be coated by a corrosion-resisting material layer. The distant end of the support tube 133 can be affixed to the end flange 179 as counter center, e.g., via a locking pin, thereby fixing the axial position of the magnet assembly 130 relative to the target 178. The counter center has a sliding bushing, a bearing system, or the like, which allows the fixation of the magnet assembly to the end flange 179 without preventing the end flange from rotating together with the target 178.

FIG. 17C is a perspective view of the magnetron assembly shown in FIG. 17A. The magnet assembly 130 is firmly attached to the second support member. It can be seen that the magnetic structure 132 of the magnet assembly is formed with bulge in its central portion, between respective end portions of the same magnetic structure.

In some embodiments of the invention, the magnet assembly may have a segmented magnetic structure, e.g. comprise at least two consecutive segments in the longitudinal direction of the magnetic structure corresponding to a length direction of the sputter target. For instance, the respective end portions of the magnetic structure and the central portion may be segments, which facilitates the exchange of differently shaped end portions for different target designs, e.g. to conform better to dog bone shaped targets. A support for the magnetic structure may be magnetic, e.g. a magnetic support tube, and acts as a pole piece. The support for the magnetic structure may be shaped as a hollow cylinder or as an angular segment thereof. Alternatively, the support for the magnetic structure may be provided as a plurality of support plates that are mounted with a particular azimuthal orientation with respect to the rotation axis of the magnet assembly. However, a support tube, or segmented support tube with only few segments is easier to assemble and align. A radial position of the magnet assembly may be adjustable globally, or in case of segmented magnet assemblies, also locally, e.g. by means of mechanical interposers like shims or by means of hydraulic, pneumatic or electrical actuators.

It is an advantage of embodiments of the invention that a coating layer can be deposited uniformly over large areas of substrates or workpieces that are non-flat, e.g. curved or having a varying height profile, or mounted at an angle relative to a substrate carrier plane or substrate transport direction. Typical width and length dimensions of (curved) large-area substrates are, e.g., 0.3*0.4 m² , 1.1*1.3 m² , 1.5*1.8 m² , 1.0*6.0 m² , 2.0*2.0 m² , 2.0*3.0 m² or 2.9*3.2 m². It is a further advantage of embodiments of the invention that the deposited layer thickness on large-area, non-flat or inclined substrates can be controlled accurately, e.g. within +/−5% or less, e.g. accurate within +/−3% or +/−1%.

It is a further advantage of embodiments of the invention that multiple substrates of different height (thickness) or surface orientation can be sputter-coated in parallel, e.g. if mounted on a common transport frame or arranged into columns that are substantially parallel to the length axis of the rotary target.

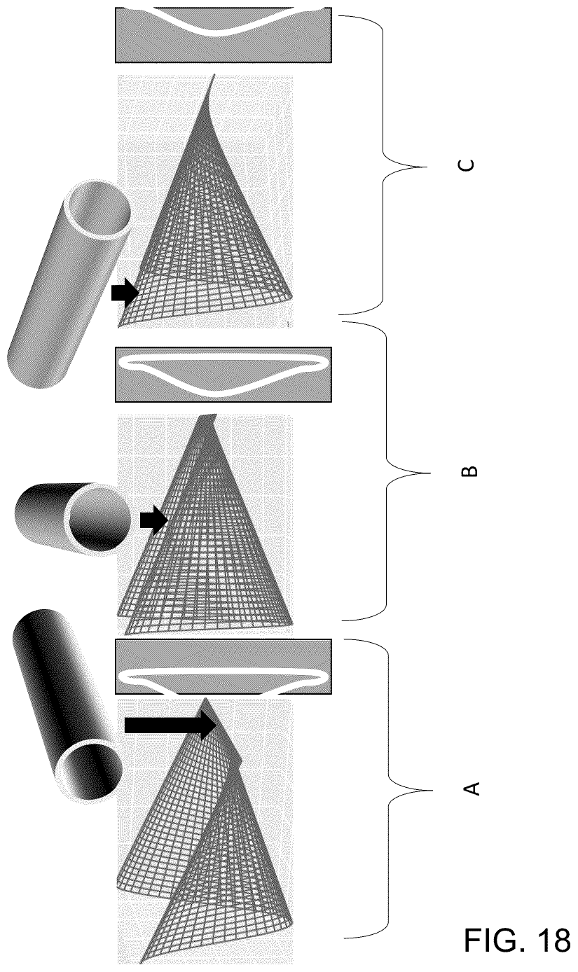

FIG. 18 explains how a uniform coating layer can be deposited onto a curved substrate by a magnetron sputter apparatus that includes the magnetron assembly of the first aspect of the invention. The curved substrate surface facing the target has a complex overall shape. Along the length direction of the substrate, which is oriented in the substrate transport direction, the substrate surface shape can be characterized by: a flat leading edge; a depression in the middle portion that is flanked by upraising slanted edges delimiting the substrate width in a direction parallel to central rotation axis of the rotary target; and a trailing edge which is a continuation of the middle portion, having a more pronounced depression flanked by even more elevated, slanted edges. Three phases A-C during the sputter coating process of the curved substrate correspond to the three moments in time during which the leading edge, the middle portion and the trailing edge of the substrate are respectively positioned below the sputter target. Also shown are the respective angular or azimuthal positions of the plasma racetrack for each one of the three phases, which varies according to the rotation angles of the magnet assembly in the interior of the hollow target tube. During all three phases A-C, the sputter target is continuously rotating about the common rotation axis, independent of a rotary motion of the magnet assembly about the same axis inside the hollow target.

The plasma racetrack has the shape of a pith-style, narrow-brimmed hat, which resembles the shape of a lemon half or clothes hanger. It comprises a straight leg and a curved leg in a central portion, which are joined and terminated by turnaround segments as end portions. The curved leg presents a bulge in the central region of the cylindrical target, which reduces in amplitude towards the terminal turnaround portions of the plasma racetrack and joins straight leg portions in the transition regions between the central region and the end regions of the racetrack.

Starting with phase A, a substantially straight leg of the plasma racetrack is oriented towards and facing the leading edge of the substrate. A particle flux of the sputtered material, predominantly generated by the straight leg of the plasma racetrack, is substantially uniform across the substrate width. This causes a thickness profile of deposited material on the substrate surface that is uniform along the length direction of the target. During phase B, both the straight leg and a curved leg of the plasma racetrack are oriented towards and facing the middle portion of the substrate, albeit with different tilt angles. As the rotation angle of the magnet assembly is adjusted as a function of the substrate position relative to the target, the straight leg is progressively tilted outwards, following the leading edge of the moving substrate, while the bulge of the curved leg is progressively turned towards the bottom of the depression in the substrate surface. In consequence, the particle flux of the sputtered material generated by the curved leg of the plasma racetrack contributes more strongly, compensating the growing distance between the depression in the substrate surface and the sputter target. At the same time, the contributions to the particle flux of the sputtered material that are generated by the straight leg and the end portions of the plasma racetrack becomes weaker, which compensates for the shrinking distance between the upraising outer edges of the substrate surface and the sputter target. In combination, a uniform deposition rate and film thickness can be obtained across the substrate width in its middle portion. In phase C, the magnet assembly has been rotated to an extent that only the bulge of the curved leg is facing the trailing edge of the substrate. The particle flux of the sputtered material is predominantly generated by the bulged portion of the curved leg, concentrating the emission of sputter particles in the center of the sputter target. This balances the adverse factors of maximum spacing between the bottom of the depression in the substrate surface and the sputter target on the one hand and minimum spacing between the slanted side edges and the sputter target on the other hand.

At the end of phase C, when the substrate leaves the sputtering zone, or when the substrate exits the deposition chamber via a valve gate, the magnet assembly may be rotated back to a homing position, e.g., an initial rotational position in which the magnet assembly is tilted in such a way that the straight leg faces the entry slit of the deposition chamber. Other homing positions may be defined. The magnet assembly is halted in the homing position until the next substrate enters the deposition chamber and is then rotated progressively towards the configurations as shown in the subsequent phases A to C. In a continuous coating process, the above process repeats for each new substrate that enters the deposition chamber. The magnet assembly thereby performs an oscillating, rocking movement about its rotation axis, which is synchronized to the substrate position relative to the sputter source but not necessarily a steady movement.

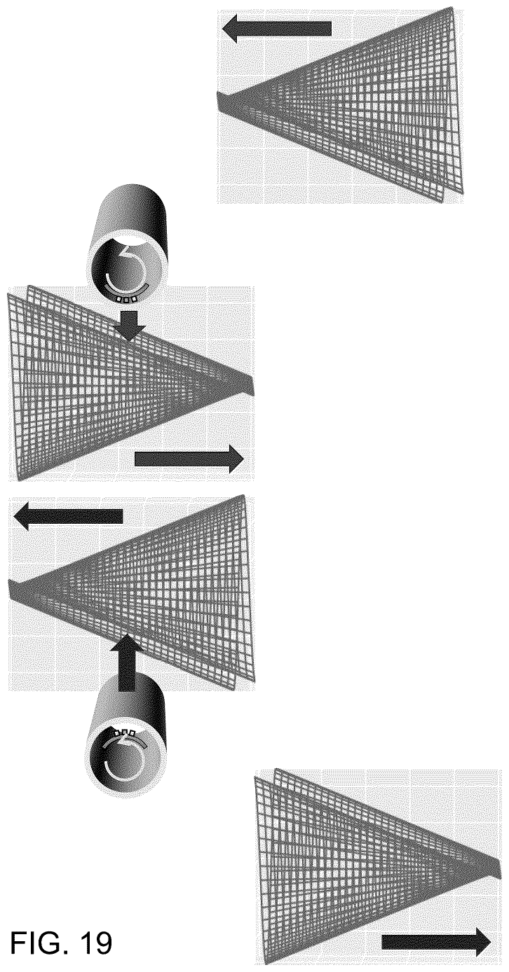

FIG. 19 is a schematic of a magnetron sputter apparatus according to an alternative embodiment, in which the rotary motion of the magnet assembly about its rotation axis is continuous and unidirectional. A second substrate conveyor system or transport means is advantageously provided opposite to the first substrate conveyor system such that the cylindrical target with magnet assembly is positioned in between the two substrate conveyor systems or transport means. The magnetron sputter apparatus may be a horizontal or vertical inline coater. Substrates transported by the first and second conveyor system move along opposite directions. Embodiments of this kind have the advantage that the magnet assembly does not have to be rotated back to the homing position before the coating process for a new substrate is started. Hence, a higher throughput can be obtained.

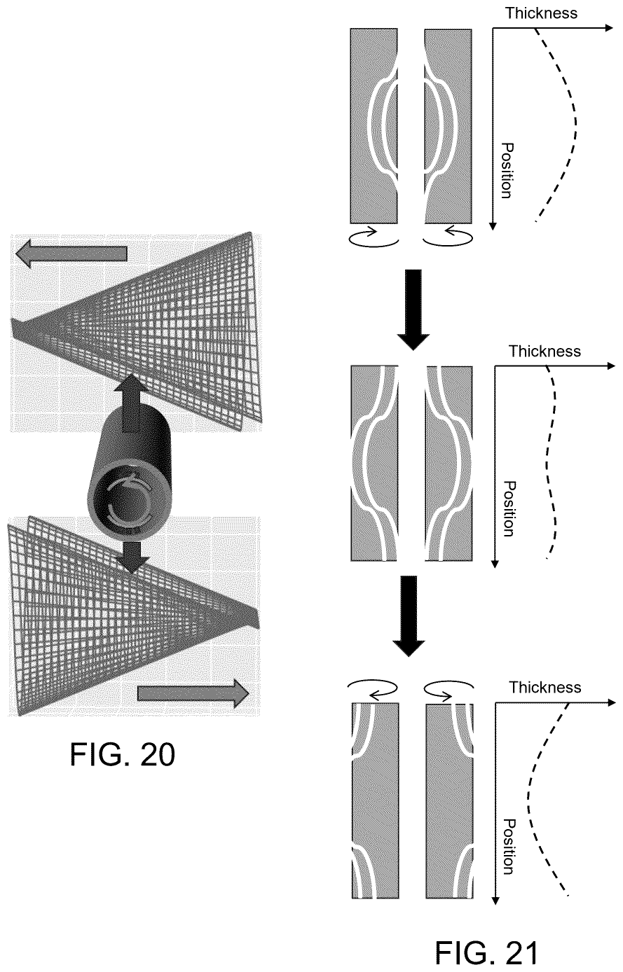

FIG. 20 is an alternative of the embodiment shown in FIG. 19. A second magnet assembly is mounted inside the cylindrical target, whereby a further closed-loop racetrack can be induced simultaneously. Two substrates are mounted on a respective transport means and have their surfaces to be coated facing each other. The substrates are transported along opposite directions during the simultaneous coating process. Dark space shields (not shown) may be arranged around the cylindrical target to avoid sputtered material to leave the target in undesired directions.

FIG. 21 is a schematic of a dual magnetron sputter apparatus according to yet another embodiment. The dual magnetron sputter apparatus comprises two substantially coaxially aligned sputter sources. Each sputter source comprises an assembly according to an embodiment of the first aspect, e.g. an end block magnetron assembly, and a cylindrical target mounted on the support member of the assembly. The magnetic structures and the thereby induced plasma racetracks preferably are shifted mirror images of each other, but are not limited thereto. The rotary motion of the magnetic structure inside each target tube is synchronized to a position of the moving substrate relative to the dual sputter source. In some embodiments, the rotary motion of the magnetic structures inside the second target tube is locked to the rotary motion of the magnetic structures inside the first target tube so that the two magnetic structures and thereby obtained plasma racetracks are moved in unison, but in opposing sense of rotation. Similar to the embodiment of FIG. 18, three distinct phases of a coating process as seen by an observer moving with the substrate are illustrated in FIG. 21 from the top to the bottom. As the magnetic structures inside the target tubes are rotated while the substrate is moved past the dual sputter source, the non-uniform thickness profile along the substrate width (corresponding to length direction of the elongated targets) changes from sputter phase to sputter phase.

In one phase of the sputter coating process (top part of FIG. 21), the bulged zones formed by the two substantially equidistant legs of each plasma racetrack are oriented towards each other and point towards a common region on the substrate surface (not shown). This leads to an increase in the deposition rate and sputtered film thickness in a middle zone of the substrate surface, corresponding to a central portion of the targets. In another phase of the sputter coating process (middle part of FIG. 21), the bulged zones formed by the two plasma racetrack are tilted away from each other and point towards a different regions on the substrate surface. At the same time, the transition zones formed by the substantially equidistant legs between the central portion and the end portion of each plasma racetrack are now oriented towards each other and point towards a respective common region towards either end of the substrate surface. This leads to an almost uniform deposition rate and sputtered film thickness across the width dimension of the substrate surface (corresponding to a central portion of the targets). In a further phase of the sputter coating process (bottom part of FIG. 21), the bulged zones formed by the two plasma racetrack are tilted even further away so that they do not face the substrate surface anymore. Also the transition zones between the central portion and the end portion of the plasma racetracks are now oriented away from each other and point towards distinct regions of the substrate surface. This leads to a decrease in the deposition rate and a depression in the sputtered film in the middle zone of the substrate surface. In consequence, a flat substrate can be coated with a non-uniform layer for which the deposited layer thickness can be controlled locally with good accuracy. In contrast thereto, a curved substrate for which the local target-to-substrate distance changes during substrate transport in the same way as set out by the changing layer thickness/sputtered material flux density with respect to flat substrates in the different sputter phases can be coated with a layer that is uniform across the substrate.

Although a magnetron sputter apparatus with two sputter sources is shown in this example, it is possible to add more sputter sources along the transport path of the substrate in the deposition chamber. A distance between adjacent similar target tubes may be advantageously chosen such that target material leaving a target tube is partially sputtered onto one or more neighboring target tubes.

Embodiments of the invention have been described in which a shape and curvature of the magnetic structure of the magnetron assembly cause a substantial difference in the radially outward directed material flux of sputtered particles (radial component) along the length direction of the target and for at least one rotation angle of the magnet assembly, e.g. for any rotation angle of the magnet assembly, during sputtering conditions. In other words, the radial component of the material flux of sputtered particles (understood as a vector field) is a function of the axial position along the common rotation axis of the hollow target and the magnet assembly and varies substantially along the length axis of the target, in particular between different parts of the central portion of the magnetic structure and/or between the central portion and the end portions of the magnetic structure. In embodiments of the invention, the shape and curvature of the magnetic structure is such that a material flow rate of sputtered particles across any distant plane parallel to the common rotation axis of the hollow target and the magnet assembly (understood as a scalar field) varies substantially along the length direction of the target for at least one rotation angle of the magnet assembly, e.g. for any rotation angle of the magnet assembly in a predetermined range of rotation angles. It may also vary substantially in a direction perpendicular to the length direction of the target. The distant plane parallel to the common rotation axis may correspond to a transport plane on which the substrate moves along and past the sputter target, e.g. a plane identical or parallel to a conveyor belt or a movable holding frame for substrates. Moreover, the shape and curvature of the magnetic structure is such that the material flow rate of sputtered particles across the distant plane parallel to the common rotation axis is a dynamic quantity that undergoes substantial changes when the magnet assembly is rotated about the common rotation axis during sputtering conditions. For instance, the material flow rate of sputtered particles that crosses the distant plane parallel to the common rotation axis along a reference line depends on time, e.g. defines a time-dependent relationship (e.g. curve or profile) between the deposited layer thickness and the position along the width dimension of the substrate. The reference line may correspond to the line of intersection between the distant plane parallel to the common rotation axis and a plane containing the common rotation axis, e.g. a plane that is also perpendicular to the distant plane such that the reference line is the normal projection of the common rotation axis onto the distant plane.

In another aspect, the present invention relates to a method of manufacturing a magnetron assembly according to embodiments of the first aspect. A magnetron assembly manufactured in accordance with such a method is advantageously used as part of a magnetron sputter apparatus in a continuous coating process for non-planar substrates.

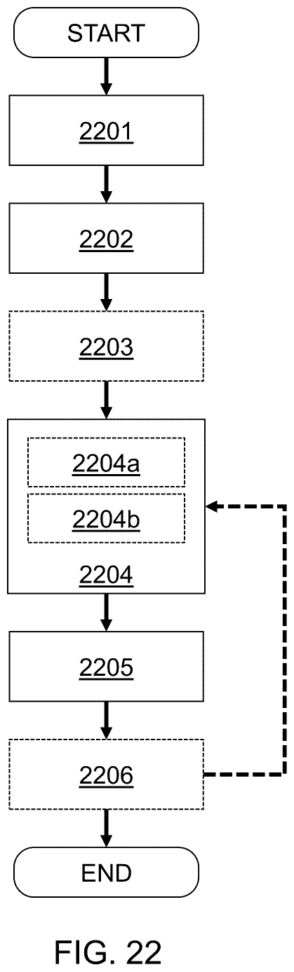

FIG. 22 is a flow diagram explaining steps of a manufacturing method for the magnetron assembly, in accordance with embodiments of the invention. In a first step 2201, surface shape information with regard to a curved substrates is obtained. This information may be retrieved or extracted from a CAD-file for the curved substrate, e.g. include the sub-steps of loading the CAD-file from a data storage device (e.g. file server) and extracting the surface shape from the loaded CAD-file. The surface shape information may be directly accessible in the file or may be derived from other quantities, e.g. derived from the substrate width and height dimensions, its surface class with in a set of predefined surface classes (e.g. parabolic, hyperbolic, saddle shape, etc.), and its principal curvature values. Alternatively, the surface shape can be reconstructed from a point cloud obtained by direct shape or height profile measurement, e.g. optical distance measurements, laser surface scanning techniques, time of flight cameras, or the like. Other means for obtaining the substrate surface shape information may be known and readily available to the skilled person.

A data processing device receives the substrate shape information as input in step 2202. Additional information regarding the inline coater geometry and configuration, e.g. the target substance, minimum target-to-substrate spacing, shield geometry, substrate orientation during transport, substrate transport trajectory through the deposition chamber, sputter process parameters, etc., may be provided to the data processing device in step 2203. Based on the received information from steps 2202 and 2203, the data processing device determines the optimal shape for the central portion of the magnetic structure of the magnetron assembly in step 2204.

Determining the optimal shape may include determining the optimal shape, global and/or local curvature of the magnetic components in the central portion of the magnetic structure, the projecting walls or traces of the magnetic components in the central portion of the magnetic structure, or the pole lines connecting equal poles of adjacent magnets in a magnet array assembled on a magnetic pole piece. The shapes and curvatures of other portions of the magnetic structure, e.g. transition regions or end portions/U-turns, may be optimized too. Use of magnetic pole pieces or magnetic shunts, magnets of different sizes and shapes, magnetic materials with adjusted energy product (BH) may be considered in order to generate the desired spatial magnetic field distribution. The shape of the central portion of the magnetic structure is optimized with respect to an optimization goal/variable, e.g. thickness uniformity of the deposited layer across the whole substrate surface.

Step 2204 may include the subs-step of running a simulation model for the coating process 2204a, assuming a substrate that is formed according to the received substrate shape information, to predict the optimization variable, e.g. to predict the overall layer thickness uniformity. The reference curves and graphs in FIG. 15 and FIG. 16 may be used to this effect. Alternatively, a surrogate model for the coating process may be executed, with the received substrate shape information as input. The shape of the central portion of the magnetic structure may then be adapted in step 2204b in a way that further maximizes or minimizes the optimization variable (shape parameter search). For instance, the initial shape for the central portion of the magnetic structure may start with two straight paths as in a conventional racetrack, and finding better shapes of the central portion may be formulated as a curve fitting problem, e.g. spline interpolation. The quality of each fit (e.g. spline) is then evaluated by the prediction method (e.g. simulation model or surrogate model). The sub-steps 2204a-b may be repeated to iteratively improve the shape of the central portion.

According to some embodiments of the invention, the shape of the central portion of the magnetic structure is optimized in conjunction with one or more variables of the coating process in the following non-exhaustive list: a control trajectory for the rotational positions of the magnetic assembly, an improved transport trajectory for the substrate, a control trajectory for the electrical power applied to the target. Rotational positions of the magnetic assembly are preferably synchronized with substrate positions relative to the sputter target. The control trajectories or transport trajectories of the co-optimized process variables are preferably sent back for storage on the data storage device. Fit-for-use drive means for rotating the magnetic assembly are generally provided, which may require absolute positioning and appropriate angular velocity control.

Next, a magnetic structure is provided as part of a magnet assembly and the azimuthal position of at least the central portion of the magnetic structure is varied between the respective end portions of the magnetic structure, in accordance with the optimal shape as determined by step 2204. This may comprise adjusting the location of individual magnets of a magnet array attached to a magnetic pole piece, or machining a magnet bar from a soft iron material into the prescribed shape (e.g. cutting, milling). The magnet assembly is rotatably mounted on at least one end block of the magnetron sputter apparatus in step 2206, such that the magnetic structure extends longitudinally along the rotation axis of the magnet assembly. Optionally, properties of the coated substrate-coated with a magnetron sputter apparatus comprising the magnetron assembly manufactured by carrying out the steps of the manufacturing method-may be measured and deviations with respect to a targeted value of the property may be fed back to step 2204, where it can be used to further optimize the shape of at least the central portion of the magnetic structure during a redesign or product refinement cycle. The measured properties of the coated substrate may include layer thickness, layer thickness uniformity, layer density, layer composition, and/or any other layer property, e.g. being mechanical (e.g. hardness, stress, roughness, etc.), optical (e.g. refractive index, absorptance, etc.), or electrical (e.g. resistance, etc.).

The above-described method of manufacture is merely illustrative and may be applied analogously to the manufacture of magnetron assemblies for the purpose of non-uniform, custom coatings on planar substrates.

The present invention is also directed to the use of a magnetron assembly according to embodiments of the first aspect in the process of sputter-coating a non-planar substrate, e.g., a curved substrate. The magnetron assembly may be obtained by carrying out the steps of the previously described manufacturing method. The sputter-coating process comprises transporting a curved substrate to be coated past the magnetron assembly, e.g., by mounting the curved substrate onto a carrier or frame of a horizontal or vertical transport system such as a roller-based or a belt-based conveyor system. Preferably, the curved substrate is oriented relative to the magnetron assembly during transport such that an axis of curvature of the curved substrate is parallel to the rotation axis of the magnet assembly, and is maintained in this orientation during the transport. The sputter-coating process further comprises synchronizing a rotational movement of the magnet assembly inside an elongated rotary sputter target with the transport trajectory of the curved substrate past the magnetron assembly. The rotary sputter target is mounted on the same end block as the magnet assembly and has an axis of rotation that is parallel and preferably coaxial with the rotation axis of the magnet assembly. Typically, the sputter target is rotated about its rotation axis during the sputter process. A separate drive means, e.g. a motor and belt system, and/or gearing system or even a direct drive system, different from the drive means for rotating the magnet assembly, is used to impart a rotary motion to the sputter target. The synchronization of the rotational movement of the magnet assembly inside the rotary sputter target with the transport trajectory of the substrate past the sputter source may be performed by a controller. The controller may load and use the control trajectories that have been stored on the data storage device, when carrying out step 2204 of the embodiment of FIG. 22, to determine a control signal or signal sequence for the drive means for the magnet assembly. The controller precisely times and sends the control signal to the drive means for the magnet assembly. Sensor data, e.g. position data with respect to the moving substrate, may be supplied to the controller for analysis, timing and feedback control of the drive means for the magnet assembly. For instance, position sensors are placed at the entrance and exit slits of the deposition chamber, and optionally also along the transport path of the substrate through the chamber, and send their measurement data to the controller. The controller may initiate a rotary motion of the magnet assembly by generating and applying a control signal to the drive means for the magnet assembly as soon as the substrate is detected at the entrance slit of the chamber. Likewise, the controller may force the magnet assembly back to a homing position by generating and applying an adequate control signal to the drive means for the magnet assembly as soon as the substrate is detected at the exit slit of the chamber. Measurement data collected by position sensors installed between the entrance and exit slit may be analyzed by the controller to detect any deviation from the planned substrate trajectory past the sputter source. Detected deviation are advantageously used by the controller to adjust, correct or fine-tune the rotary motion of the magnet assembly through the generation of corresponding control signals to the drive means. Further measurement systems (e.g. spectral optical measurements) may be provided inside or at the exit of the coating line for measuring a layer property of the substrate. Deviations and correction data can also be derived, alternatively or in addition to the measurement data from the position sensors, from measurement data collected by one or more of the further measurement systems, and a corresponding feedback signal may be sent to the controller to adjust or finetune the motion of the magnet assembly. A fully automatic feedback control method with respect to the rotary motion of the magnet assembly can thus be obtained in embodiments of the invention. Preferably, the controller is configured to support and execute control loops for rotary motion of the magnet assembly.

In yet another aspect, the present invention relates to a magnetron sputter apparatus or inline coater apparatus that includes the magnetron assembly of the first aspect of the invention.

Typically, the magnetron sputter apparatus comprises a vacuum chamber with an entrance and exit slits through which the substrate to be coated continuously enter and leave the deposition chamber, respectively. The entrance and exit slits may be part of a pair of gate valves that connect the deposition chamber to load locks, purge chambers or further deposition chambers along the coating line of the sputter apparatus. A transport means such as rollers or a conveyor belt transports the substrates to be coated through the deposition chamber and past the sputter source. During transport, the substrates to be coated are preferably secured to substrate holders or frames. The magnetron sputter apparatus may be configured as a horizontal or vertical coater. In the horizontal design, the substrate surfaces to be coated are oriented parallelly to the floor and perpendicularly to the direction of gravity, whereas the substrate surfaces to be coated are oriented perpendicularly to the floor and in the direction of gravity in the vertical design. The sputter source typically comprises an end block that is mounted inside the vacuum chamber (e.g. side mount or drop-in) and has an interface with external and non-vacuum parts of the sputter apparatus. In particular, the interface provides a feedthrough for a coolant, an electrical feedthrough, and optionally a communication channel for sensor and control data. Force transmission structures that independently transmit the driving forces of external drive means to the first and second support member of the magnetron assembly, so that a rotary motion is imparted independently on the first and second support member, may also be arranged in the end block and partly in the interface. A coolant-typically water-is generally needed to remove heat from the tubular target and the inner components of the magnetron assembly, which is generated during sputtering, whereas electrical power needs to be supplied to the rotary target. The end block also provides electrical insulation means for protecting sensitive electronics and accessible parts of the magnetron housing from the high-power electrical signal that is applied to the target during sputtering, as well as sealing cassettes for liquid sealing of the coolant circuit and vacuum sealing, which prevent liquid leaks, outgassing into and contamination of the deposition chamber.

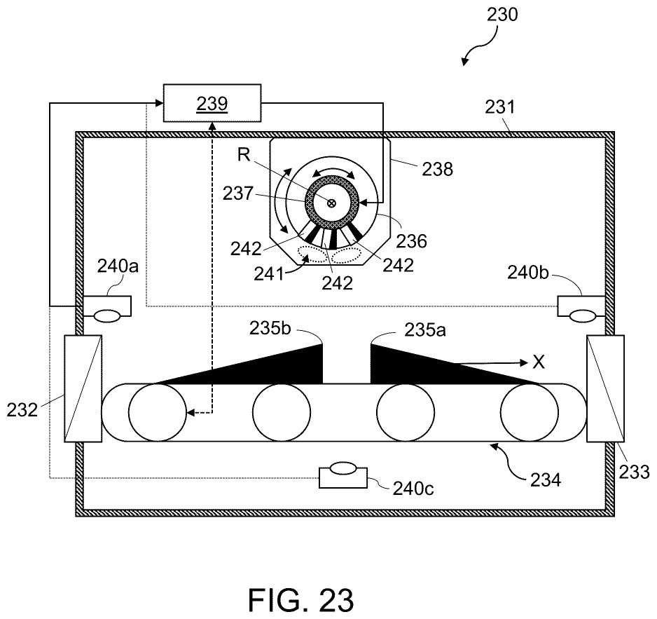

FIG. 23 is an illustrative example of a magnetron sputter apparatus 230 shown in cross-section, which includes an assembly according to the first aspect. The magnetron assembly comprises at least one end block 238 that is mounted inside a vacuum chamber 231. Independent drive means (not shown) for the first and second support member of the magnetron assembly, e.g. motor-belt or motor-gear systems, may be compactly arranged inside the end block 238 or provided in a drive box that is attached externally to the chamber wall. In the latter case, force transmission structures or components that adequately transmit the generated driving force are provided and extend through the interface of the end block, which may also contain feedthroughs for the coolant and the electrical power signal. Alternatively, the coolant and/or electrical feedthrough are arranged in an opposite, second end block. If present, the second end block may also comprise one of the two drive means and corresponding support members. Force transmitting structures may include two separate drive shafts or spindles onto which flanges or disks are mounted as first and second support members, respectively. Alternatively, an end portion of the drive shaft or spindle may be adapted to receive and support the target and the magnet assembly directly. In the magnetron sputter apparatus 230, a cylindrical target 236 is mounted, e.g. clamped, onto the rotatable first support member (not shown) and the magnet assembly 237 is mounted onto the rotatable second support member (not shown). Rotation axes of the first and second support member are coaxial in the present example and define a common rotation axis ‘R’. In other embodiments of the invention, the rotation axes of the first and second support member may be parallel but offset with respect to each other. The magnet assembly 237 comprises a tubular magnetic component (e.g. a hollow soft iron cylinder) that acts as a pole piece and is firmly mounted onto a support tube which also carried the coolant in its interior and co-rotates with the support tube. The support tube, in turn, is firmly mounted onto the second support member, e.g. mounting flange, and rotates together with the second support member, which may be through a connected drive shaft in embodiments of the invention. A magnetic structure 242 of the magnet assembly 237 is formed by three rows of magnets 242, e.g. three magnet arrays or magnet tracks. Magnets of the central row have associated magnetic poles of a first magnetic polarity in the vicinity of the surrounding target 236 (i.e. distant to the tubular magnetic component and support tube) and magnets of the two peripheral or side rows have associated magnetic poles of a second magnetic polarity, opposite to the first magnetic polarity, in the vicinity of the surrounding target 236 (i.e. distant to the tubular magnetic component and support tube). The magnets of the central row and/or the peripheral rows may have a profiled top shape, or may be slightly inclined (e.g. via angled indentations in the tubular magnetic component into which the respective magnets are placed and fastened) relative to each other, so that they better conform to the circular inner surface of the target 236. A protective tubing or housing (not shown) of the magnet assembly may be arranged circumferentially around the magnetic structure 242, between the magnetic structure 242 and the target 236, to avoid corrosion of the magnet assembly by the cooling fluid, e.g. water. In the figure, the dark areas of the magnetic structure 242 corresponds to the outer walls of the curved zones of the magnet rows in the central portion of the magnetic structure. A plasma racetrack or plasma tunnel 241 is induced by the magnetic structure 242 under sputtering conditions of the magnetron sputter apparatus, i.e. when also an electrical power signal is supplied to the mounted target cylinder 236.

Substrates 235a-b to be coated continuously enter and exit the deposition chamber 231 through corresponding slits 232, 233. A conveyor belt 234 transports the substrates 235a-b across the chamber 231 and past the sputtering source. As indicated, the substrates 235a-b may have a height profile, a sloping surface, or a curved surface to be coated in a direction of substrate transport ‘X’, which leads to varying minimum distance between the target and points on the substrate surface to be coated. In addition, the substrate surface may have a height profile or surface curvature in the direction of the common rotation axis 'R'. In order to obtain a uniform coating thickness across the substrate surface to be coated, the sputter flux reaching the substrate surface has to be modulated dynamically as a function of the substrate position relative to the sputter target. Again, the sputter flux may also be varied along the direction of the common rotation axis ‘R’ to account for curved and/or profiled substrate surfaces. More generally, a desired material flux can be determined in respect of each point on the substrate surface to be coated, or in respect of each cell of a mesh generated with respect to the substrate surfaces, which comprises a plurality of cells. Preferably, the precise substrate surface to be coated is known beforehand, e.g. determined through distance or surface scanning measurements (e.g. optical ranging or time-of-flight) performed outside or inside the vacuum chamber (e.g. in a load-lock section), or extracted from CAD files. As explained in the preceding methods, the desired shape of the magnetic structure-in particular the parametrized curve describing the path of the magnetic racetrack in the central portion of the magnetic structure- and an associated control trajectory for the rotary motion of the magnet assembly can be computed from the desired material flux profile across the substrate length (along ‘X’ axis) and width (along ‘R’ axis), taking into account the geometry of the coating zone in the sputter apparatus (e.g. target-to-substrate base spacing, shield geometry, target-substrate overlap, etc.). The shape and curvature of the magnetic structure 242 of the magnet assembly 237 closely follows, and ideally matches, the computed shape. Different magnetic assemblies 237 for different substrate types and shapes can be designed and exchanged in the different campaigns. A controller 239 is configured to receive the control trajectory for the rotary motion of the magnet assembly 237 about the common rotation axis ‘R’ and generate corresponding control signals for adjusting an angular position of the magnet assembly 237. The control trajectory and the corresponding control signals may define a specific rotation angle of the magnet assembly 237 as a function of the substrate position relative to the sputter target; more precisely, the substrate position relative to the projection of the rotation axis ‘R’ onto a reference plane parallel to the transport plane of the conveyor 234. The relative position of the substrate may be inferred from the time the substrate enters the chamber 231 via the entrance slit 232 and the predetermined or measured transport speed of the conveyor 234. A position sensor 240a may determine the moment in time when the substrate enters the chamber 231 and send a trigger signal or communicate the entrance time to the controller 239, which uses this information to synchronize the controlled rotary motion of the magnet assembly 237 (i.e. by controlling the second drive means) with the movement trajectory of the substrate across the deposition chamber. Additional position sensors 240b, 240c may be arranged along the conveyor 234 to accurately locate the substrate in the deposition chamber while it is transported. This and other sensor information, e.g. including sensor information related to process parameters such as partial gas pressures, target temperature, electrical power supplied to the target, magnetic field strength along plasma racetrack 241, etc., is advantageously communicated to the controller 239 to achieve feedback control and detect potential malfunctioning or critical operating conditions of the sputtering apparatus 230. That is, the additional sensor data is received as feedback input data by the controller 239, which is executing a control loop. This allows instantaneous correction of the rotation angle of the magnet assembly 237 and/or a change in the transport speed of the conveyor 234 as a result of deviations in the expected sensor data, as detected by the controller 239, and/or as a result of pre-characterized imperfections of the magnetron sputter apparatus. Deviations that require feedback control may be irregularities in the substrate movement during transport, irregularities in the rotation of the magnet assembly 237 about the rotation axis ‘R’, or the like. Pre-characterized imperfections of the sputter apparatus may include factors like the slowly changing target erosion profile, the imperfect manufacture of the shape of magnetic structure 242 relative to the computed shape (and which cannot be compensated adequately, e.g. via shunts along the magnetic racetrack), minor sample to sample variations of the surface shape of the substrate, e.g. as measured prior to loading the substrate into the chamber 231, etc.

Above considerations for the coating layer thickness similarly apply to the uniformity of other layer properties: optical layer properties (e.g. uniform refractive index, reflectance coefficient, extinction coefficient, etc., across the coated substrate), electrical layer properties (e.g. uniform sheet resistance, etc., across the substrate), magnetic layer properties (e.g. uniform magnetoresistance or magnetic tunnel resistance, etc., across the substrate), mechanical layer properties (e.g. uniform roughness, hardness, stress, elasticity, etc., across the substrate), or morphological layer properties (e.g. uniform crystal structure, crystal orientation, density, etc., across the substrate). A position sensor 240b at the exit slit 233 may detect the moment in time when the coated substrate is about the leave the deposition chamber 231 and generate a trigger signal that causes the controller 239 to initiate a homing sequence that rotates back the magnet assembly 237 to a starting angle. Advantageously, the trailing edge of a currently coated substrate 235a corresponds to the leading edge of the next substrate 235b, identical to the current substrate 235 a but rotated by 180°with respect to the current substrate 235 a, in the continuous coating process, which eliminates the need to carry out the homing sequence of the magnet assembly between any two consecutive substrates 235a, 235b. Instead, the rotation angle trajectory through time is simply inverted between the two consecutive substrates.

Furthermore, measurements may be carried out behind the coating zone, subsequent to the coating process, to help understanding the deposited material profile across the substrate (width and length). The collected measurement data can then be used to achieve further fine-tuning of the sputtered material flux at or near the substrate surface, by adjusting one or more of the following: changing a control parameter in the control loop of the parametrized controller algorithm, changing the shield opening, tuning the magnet assembly (global and/or local repositioning, manual and/or online).

In embodiments of the invention in which a shield assembly with a shield for the sputter target is provided, the shield opening is coplanar with the reference line, i.e. is coplanar with the normal projection of the rotation axis of the second support member onto the distant plane, e.g. the transport plane of the substrates being moved past the magnet assembly and sputter target. That is sputtering along a direction perpendicular to the magnet assembly and the sputter target outer surface towards the exposed top surface of substrate passing beneath the sputter target is possible. In such embodiments of the invention, the shield opening extends longitudinally along the rotation axis of the second support member and is configured to expose a portion of the sputter target's outer surface. The shield opening may be centered about the plane that is normal to the sputter target's outer surface and contains the reference line, e.g. the shield opening is arranged parallel to and aligned with (i.e., no offset) the sputter target in the chamber of the sputter apparatus. Compared to sputtering at acute angles, sputtering at right angles with respect to the exposed top surface of a substrate passing below the sputter target has the additional advantages of being more efficient (higher deposition rate), allowing for higher throughput, and reducing debris formation on the shields, whereby the risk of sample defects and impurities on coated surfaces is lowered.

In variants of the described magnetron sputter apparatus, multiple similar sputter targets and magnetron assemblies, e.g. at least two similar sputter sources, are mounted along the coating line in the same deposition chamber. This has the additional advantage of reducing the amount of material that is lost by sputtering onto shields. Instead, multiple sputter sources mutually sputter and receive the target material onto each other. In variants of the embodiment that use multiple sputter sources with similar magnet assemblies, the magnetic structures of adjacent assemblies may be shifted mirror images of each other (mirror plane through the rotation axis ‘R’ and shift to the rotation axis associated with the adjacent assembly). Moreover, the second drive means of the two adjacent assemblies are preferably configured to synchronize the rotary motion of one of the corresponding second support members with the rotary motion of the other one of the corresponding second support members, e.g. rotating to the same angles, to inverse angles or scaled angles, possibly with a time shift/delay (in the drive signals). The controller 239 may be programmed to orchestrate the additional synchronization among several magnetron assemblies.

While the invention has been illustrated and described in detail in the drawings and foregoing description, such illustration and description are to be considered illustrative or exemplary and not restrictive. The foregoing description details certain embodiments of the invention. It will be appreciated, however, that no matter how detailed the foregoing appears in text, the invention may be practiced in many ways. The invention is not limited to the disclosed embodiments.

Other variations to the disclosed embodiments can be understood and effected by those skilled in the art in practicing the claimed invention, from a study of the drawings, the disclosure and the appended claims. In the claims, the word “comprising” does not exclude other elements or steps, and the indefinite article “a” or “an” does not exclude a plurality. A single processor or other unit may fulfill the functions of several items recited in the claims. The mere fact that certain measures are recited in mutually different dependent claims does not indicate that a combination of these measures cannot be used to advantage. A computer program may be stored/distributed on a suitable medium, such as an optical storage medium or a solid-state medium supplied together with or as part of other hardware, but may also be distributed in other forms, such as via the Internet or other wired or wireless telecommunication systems. Any reference signs in the claims should not be construed as limiting the scope.

1.-18. (canceled)

19. A magnetron assembly for a magnetron sputter apparatus, comprising:
a first support member and a second support member for mounting thereon an elongated sputter target and a magnet assembly, respectively,
a first drive configured to impart rotary motion to the first support member and an independent second drive configured to impart rotary motion to the second support member, separately from the rotary motion imparted to the first support member,
wherein axes of rotation of the first support member and the second support member are parallel and preferably substantially coaxial, and
the magnet assembly comprising an elongated magnetic structure extending longitudinally in the direction of the rotation axis of the second support member, a central portion of the magnetic structure being terminated by respective end portions, and the magnetic structure defining a closed-loop confinement region for a plasma generated under sputtering conditions of the magnetron sputter apparatus,
wherein the central portion of the magnetic structure has an azimuthal position relative to the rotation axis of the second support member, said azimuthal position of the central portion varying between the respective end portions of the magnetic structure,
wherein a shape of the magnetic structure is adapted to cause a substantial difference in material flux of sputtered particles at different points along a reference line, said reference line being defined as the normal projection of the rotation axis of the second support member onto any distant plane parallel to the rotation axis of the second support member.

20. The magnetron assembly of claim 19, wherein the magnetic structure and the thereby defined plasma confinement region are asymmetric with respect to any plane containing the rotation axis of the second support member.

21. The magnetron assembly of claim 19, wherein the shape of the magnetic structure is adapted to cause a substantial time-varying change in material flux of sputtered particles at the different points along the reference line, when the magnet assembly is being rotated during sputtering.

22. The magnetron assembly of claim 19, further comprising the elongated sputter target for mounting on the first flange, said sputter target being a cylindrical target.

23. The magnetron assembly of claim 22, wherein an outer diameter of the cylindrical target varies along the direction of the rotation axis of the first support member.

24. The magnetron assembly of claim 19, wherein the magnetic structure comprises at least two magnetic tracks in the central portion of the magnetic structure, connected to each other by the respective end portions of the magnetic structure, a variation in the azimuthal position of one of the magnetic tracks being at least 20° in the central portion of the magnetic structure.

25. The magnetron assembly according to claim 24, wherein the variation in the azimuthal position of both magnetic tracks in the central portion of the magnetic structure is at least 20°.

26. The magnetron assembly according to claim 25, wherein the at least two magnetic tracks are separated by a distance in the azimuthal direction that is constant throughout the central portion of the magnetic structure.

27. The magnetron assembly according to claim 19, wherein the azimuthal position of the central portion of the magnetic structure varies linearly between the respective end portions of the magnetic structure.

28. The magnetron assembly of claim 19, wherein the respective end portions of the magnetic structure have different azimuthal positions relative to the rotation axis of the second support member.

29. A magnetron sputter apparatus comprising the magnetron assembly of claim 19.

30. The magnetron sputter apparatus of claim 29, further comprising a substrate transport system for conveying one or more substrates past the magnet assembly, the distant plane parallel to the rotation axis of the second support member corresponding to a plane of the substrate transport system in which the substrates are conveyed past the magnet assembly.

31. The magnetron sputter apparatus according to claim 29, further comprising the elongated sputter target mounted on the first support member and a shield assembly having a shield with an opening adapted to expose a portion of the surface of the sputter target, the shield opening extending longitudinally in the direction of the rotation axis of the second support member and being coplanar with the reference line.

32. The magnetron sputter apparatus of claim 29, further comprising a controller configured to control a time-dependent rotation angle of the magnet assembly about the rotation axis of the second support member and synchronize a rotational movement of the magnet assembly with a transport trajectory of a substrate past the magnet assembly.

33. The magnetron sputter apparatus according to claim 32, further comprising the elongated sputter target mounted on the first support member, a substrate transport system for conveying one or more substrates past the sputter target, and a position sensor arranged along the substrate transport system,
wherein the position sensor is configured to detect a time of passage of each substrate relative to the position sensor and the controller is further configured to synchronize the rotational movement of the magnet assembly with the transport trajectory of the substrate based on the time of passage detected by the position sensor with respect to the substrate.

34. The magnetron sputter apparatus of claim 29, comprising a plurality of magnetron assemblies, and a substrate transport system having a predetermined substrate transport direction, the rotation axes of the second support members of the plurality of magnetron assemblies being substantially parallelly oriented and separated by predetermined distances along the substrate transport direction,
wherein the magnetic structures of any two adjacent assemblies of the plurality of magnetron assemblies are related by a mirror transformation and/or a scaling transformation, and
wherein the second drive of any two adjacent assemblies of the plurality of magnetron assemblies are configured to synchronize or receive control signals for synchronizing the rotary motion imparted onto one of the corresponding second support members with the rotary motion imparted onto the other one of the corresponding second support.

35. A method of manufacturing a magnetron assembly for use in magnetron sputter apparatus, suitable for sputter-coating of non-planar substrates in a continuous coating process, the method comprising the steps of:
obtaining shape information with regard to the curved substrates to be coated,
providing a magnetic structure as part of a magnet assembly and rotatably mounting the magnet assembly on an end block of the magnetron assembly,
wherein the magnetic structure extends longitudinally along a rotation axis of the magnet assembly and defines a closed-loop confinement region for a plasma generated under sputtering conditions of the magnetron sputter apparatus,
determining a shape for a central portion of the magnetic structure, terminated by respective end portions of the magnetic structure, based on the shape information obtained with regard to the curved substrates, and
varying an azimuthal position of the magnetic structure in a central portion of the magnetic structure, arranged between respective end portions of the magnetic structure, in accordance with therefore determined shape.

36. The method of claim 35, wherein determining the shape for the central portion of the magnetic structure includes optimizing the shape with respect to layer uniformity of a sputtered material layer to be deposited onto the curved substrate.

37. A method of sputter coating curved substrates, comprising the steps of:
transporting a curved substrate to be coated past a magnetron assembly obtained by carrying out the method steps of claim 35,
synchronizing a rotational movement of the magnet assembly about its rotation axis with said transporting of the curved substrate past the magnetron assembly, the magnet assembly being mounted inside a hollow sputter target rotatably mounted onto the end block of the magnetron assembly such that the axes of rotation of the sputter target and the magnet assembly are substantially parallel.
